(19) United States
(12) Patent Application Publication
(10) Pub. No.: US 2026/0231727 A1
(43) Pub. Date: Aug. 6, 2026

(54) SUBSTRATE PROCESSING APPARATUS AND SUBSTRATE PROCESSING METHOD

(71) Applicant: Tokyo Electron Limited, Tokyo (JP)

(72) Inventors: Hiromitsu SAKAUE, Nirasaki City (JP); Keisuke KONDOH, Nirasaki City (JP); Yuichi NISHIMORI, Nirasaki City (JP); Toshiki OTA, Nirasaki City (JP)

(21) Appl. No.: 19/648,109

(22) Filed: Apr. 15, 2026

Related U.S. Application Data
(63) Continuation of application No. PCT/JP2024/040629, filed on Nov. 15, 2024.

(30) Foreign Application Priority Data
Oct. 17, 2023 (JP) 2023-178622

(51) Int. Cl. H10P 72/30; H10P 72/00

(52) U.S. Cl. CPC H10P 72/3304; H10P 72/0402; H10P 72/0454; H10P 72/0464; H10P 72/0466; H10P 72/0606; H10P 72/3302

(57) ABSTRACT

A substrate processing apparatus incudes: a processing module for processing substrates placed on stages; a first transfer module including a first transfer robot for collectively transferring the substrates with respect to the processing module; a second transfer module including a second transfer robot for transferring the substrates with respect to a container; and a load lock module provided between the first and second transfer modules to accommodate the substrates transferred by the first or second transfer robot. The load lock module includes: stage regions arranged around a center of a rotary support; the rotary support including fixed support pins for supporting the substrates; and a drive mechanism for driving the rotary support in a rotational direction. When transferring the substrates between the load lock module and the first or second transfer module, the first or second transfer robot transfers the substrates with respect to the fixed support pins.

### CROSS-REFERENCE TO RELATED APPLICATIONS

This application is a bypass continuation application of International Application No. PCT/JP2024/040629 having an international filing date of Nov. 15, 2024 and designating the United States, the international application being based upon and claiming the benefit of priority from Japanese Patent Application No. 2023-178622, filed on Oct. 17, 2023, the entire contents of which are incorporated herein by reference.

### TECHNICAL FIELD

The present disclosure relates to a substrate processing apparatus and a substrate processing method.

### BACKGROUND

Patent Document 1 discloses a vacuum processing apparatus which is provided with a vacuum transfer arm including a wafer holder for holding wafers on a tip side and a base side thereof, and a vacuum processing module into which the wafers held by the wafer holder are collectively loaded for vacuum processing.

### PRIOR ART DOCUMENT

### Patent Document

Patent Document 1: Japanese Laid-Open Patent Publication No. 2018-190939

### SUMMARY

According to one embodiment of the present disclosure, a substrate processing apparatus for processing substrates includes: a processing module including a plurality of stages and configured to process the substrates placed on the plurality of stages; a first transfer module including a first transfer robot configured to collectively transfer the substrates with respect to the processing module; a second transfer module including a second transfer robot configured to transfer the substrates with respect to a container capable of accommodating the substrates; and a load lock module provided between the first transfer module and the second transfer module and configured to accommodate the substrates transferred by the first transfer robot or the second transfer robot. The load lock module includes: a plurality of stage regions arranged around a center of a rotary support; the rotary support including a plurality of fixed support pins for supporting the substrates and configured to be rotatable about the center as a rotation axis above the plurality of stage regions; and a drive mechanism configured to drive the rotary support in a rotational direction. When transferring the substrates between the load lock module and the first transfer module or the second transfer module, the first transfer robot or the second transfer robot transfers the substrates with respect to the plurality of fixed support pins.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing a schematic configuration of a wafer processing apparatus according to an embodiment.

FIG. 2 is a perspective view showing a schematic configuration of an atmospheric transfer robot.

FIG. 3 is a perspective view showing a schematic configuration of a vacuum transfer robot.

FIG. 4 is a plan view showing a schematic configuration of a processing module.

FIG. 5 is a cross-sectional view showing a schematic configuration of the processing module.

FIG. 6 is a perspective view showing a schematic configuration of a load lock module.

FIG. 7 is a plan view showing a schematic configuration of the load lock module.

FIG. 8 is a cross-sectional view showing a schematic configuration of the load lock module.

FIG. 9 is a perspective view showing a schematic configuration of a rotary plate.

FIG. 10 is an explanatory diagram showing a state in which an atmospheric transfer robot or a vacuum transfer robot enter the load-lock module.

FIG. 11 is a flow chart showing major operations of wafer processing.

FIG. 12A is an explanatory diagram showing major operations of the wafer processing in the wafer processing apparatus.

FIG. 12B is an explanatory diagram showing major operations of the wafer processing in the wafer processing apparatus.

FIG. 12C is an explanatory diagram showing major operations of the wafer processing in the wafer processing apparatus.

FIG. 12D is an explanatory diagram showing major operations of the wafer processing in the wafer processing apparatus.

FIG. 12E is an explanatory diagram showing major operations of the wafer processing in the wafer processing apparatus.

FIG. 12F is an explanatory diagram showing major operations of the wafer processing in the wafer processing apparatus.

FIG. 12G is an explanatory diagram showing major operations of the wafer processing in the wafer processing apparatus.

FIG. 12H is an explanatory diagram showing major operations of the wafer processing in the wafer processing apparatus.

FIGS. 13A to 13E are explanatory diagrams showing major operations of wafer transfer in the load lock module.

FIGS. 14A to 14C are explanatory diagrams showing major operations of wafer notch orientation control in an orienter of the load lock module.

FIG. 15 is an explanatory diagram showing a narrow pitch arrangement of four wafers.

FIG. 16 is a cross-sectional view showing a schematic configuration of a processing module according to another embodiment.

FIG. 17 is an explanatory diagram showing an example of a wafer notch orientation.

FIG. 18 is an explanatory diagram showing an example of the wafer notch orientation.

FIGS. 19A to 19C are explanatory diagrams showing major operations of the wafer processing when a heat treatment mechanism is provided in a stage.

FIG. 20 is a plan view showing a schematic configuration in which two load lock modules are integrated.

FIG. 21 is a plan view showing a schematic configuration of a wafer processing apparatus according to another embodiment.

FIG. 22 is a perspective view showing a schematic configuration of a rotary plate according to another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, various processes are performed on semiconductor wafers (hereinafter referred to as “wafers”). This wafer processing is performed in a wafer processing apparatus that includes, for example, a processing module for processing the wafers and a transfer module for transferring the wafers to the processing module.

In the vacuum processing apparatus (wafer processing apparatus) disclosed in Patent Document 1, the vacuum transfer arm transfers the plurality of wafers in a collective manner and the vacuum processing module processes the plurality of wafers in the collective manner. This reduces the size of the wafer processing apparatus and improves throughput of the wafer processing.

On the other hand, in the wafer processing apparatus that transfers and processes the plurality of wafers in the batch manner, there is a demand for improving the accuracy of transferring the plurality of wafers to the processing module in order to further achieve an improvement in an apparatus performance.

The technique disclosed in the present disclosure has been made considering the above circumstances, and is intended to improve substrate transfer accuracy in a substrate processing apparatus that transfers and processes a plurality of substrates in a collective manner. Hereinafter, a wafer processing apparatus as the substrate processing apparatus and a wafer processing method as a substrate processing method according to this embodiment will be described with reference to the drawings. In this specification and the drawings, elements having substantially the same functional configurations will be designated by like reference numerals, and redundant descriptions thereof will be omitted.

### First Embodiment: Wafer Processing Apparatus

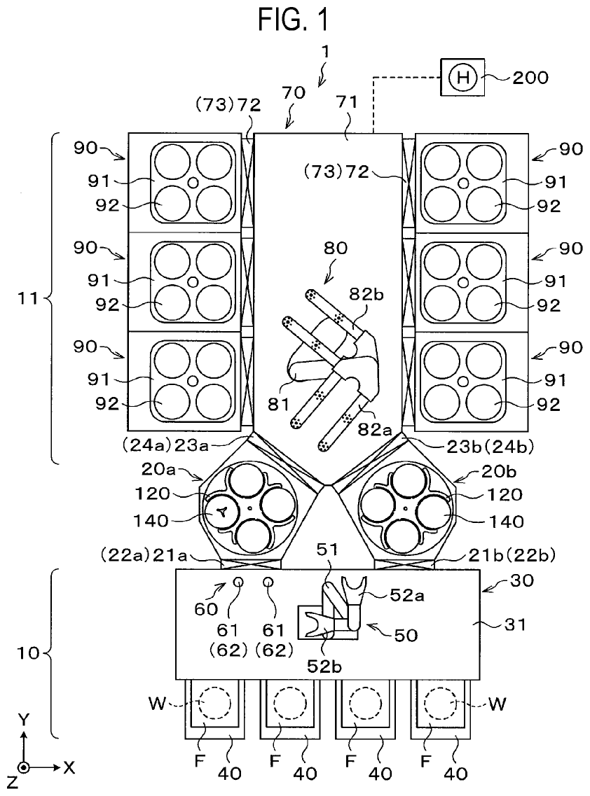

First, a configuration of the wafer processing apparatus according to this embodiment will be described. FIG. 1 is a plan view showing a schematic configuration of a wafer processing apparatus 1. In the wafer processing apparatus 1, a desired process is performed on wafers W as substrates in a vacuum atmosphere.

As shown in FIG. 1, the wafer processing apparatus 1 has a configuration in which an atmospheric part 10 and a vacuum part 11 are integrally connected to each other via two load lock modules 20a and 20b. The atmospheric part 10 transfers and processes the wafers W in an atmospheric environment. The atmospheric environment is an example of an atmospheric pressure atmosphere. The vacuum part 11 transfers and processes the wafers W in a vacuum atmosphere. The vacuum atmosphere is an example of a depressurized atmosphere.

For example, the load lock module 20a temporarily places thereon and holds the wafers W transferred from a loader module 30 (to be described later) in the atmospheric part 10 in order to deliver the wafers W to a transfer module 70 (to be described later) in the vacuum part 11. In addition, for example, the load lock module 20b temporarily places and holds the wafers W transferred from the transfer module 70 in order to deliver the wafers W to the loader module 30.

Each of the load lock modules 20a and 20b is configured so that an interior thereof may be switched between an atmospheric pressure atmosphere and the depressurized atmosphere. That is, each of the load lock modules 20a and 20b is configured so that the wafers W may be appropriately delivered between the atmospheric part 10 in the atmospheric pressure atmosphere and the vacuum part 11 in the depressurized atmosphere. Each of the load lock modules 20a and 20b is also configured so as to accommodate the plurality of wafers W, for example, four wafers W. A specific configuration of each of the load lock modules 20a and 20b will be described later.

The load lock module 20a is connected to the loader module 30 (to be described later) via a gate 22a provided with a gate valve 21a. By the gate valve 21a, the load lock module 20a and the loader module 30 are in communication with each other while airtightness therebetween is secured. The load lock module 20a is also connected to the transfer module 70 (to be described later) via a gate 24a provided with a gate valve 23a. By the gate valve 23a, the load lock module 20a and the transfer module 70 are in communication with each other while airtightness therebetween is secured.

Similar to the load lock module 20a, the load lock module 20b is connected to the loader module 30 via a gate 22b provided with a gate valve 21b, and is connected to the transfer module 70 via a gate 24b provided with a gate valve 23b. By these gate valves 21a and 23a, the load lock module 20a, the loader module 30 and the transfer module 70 are in communication with each another while airtightness therebetween is secured.

### Atmospheric Part 10

Next, a configuration of the atmospheric part 10 will be described. The atmospheric part 10 includes the loader module 30 as a second transfer module and a plurality of, for example, four, load ports 40.

The loader module 30 includes a housing 31 having, for example, a rectangular shape in a plan view. An interior of the housing 31 is maintained in the atmospheric environment. The four load ports 40 are arranged side by side on a side surface of the housing 31 in a negative Y-axis direction. The two load lock modules 20a and 20b are arranged side by side on a side surface of the housing 31 in a positive Y-axis direction via the gates 22a and 22b provided with the gate valves 21a and 21b.

The load port 40 is configured to be capable of place a FOUP F as an accommodation container thereon. The FOUP F is configured to be capable of accommodate the plurality of wafers W, for example, 25 wafers W as one lot in multiple stages at equal intervals. An interior of the FOUP F placed on the load port 40 is filled with, for example, an air or a nitrogen gas, and is sealed.

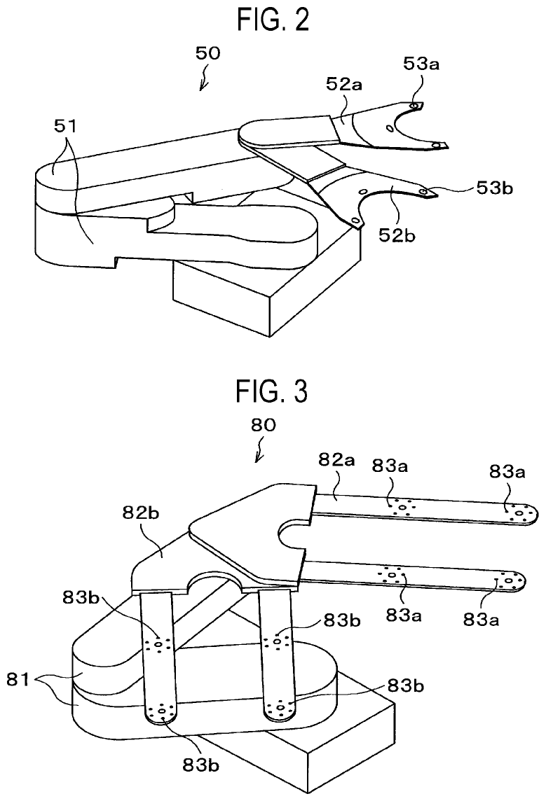

An atmospheric transfer robot 50 serving as a second transfer robot for transferring the wafers W is provided inside the loader module 30. As shown in FIG. 2, the atmospheric transfer robot 50 includes an articulated transfer arm 51. A tip of the transfer arm 51 includes an upper pick 52a serving as a second pick and a lower pick 52b serving as a second pick, which are provided in two stages. The upper pick 52a has a fork shape that branches from a base end portion to two tip end portions. Suction pads 53a are provided on surfaces of the base end portion and the tip end portions of the upper pick 52a, respectively. These three suction pads 53a attractively hold one wafer W by evacuation. The lower pick 52b has a similar configuration to the upper pick 52a, and attractively hold one wafer W by evacuation using three suction pads 53b. The transfer arm 51 is configured to be movable the upper pick 52a and the lower pick 52b in a vertical direction and a horizontal direction. The atmospheric transfer robot 50 transfers the wafers W between the FOUP F of the load port 40 and the load lock modules 20a and 20b.

As shown in FIG. 1, a position measurer 60 that measures a horizontal position of the wafer W is provided inside the loader module 30. The position measurer 60 is arranged in front of the gate valve 21a (the gate 22a) of the load lock module 20a. A known optical sensor is used as the position measurer 60. The position measurer 60 includes a light emitter 61 and a light receiver 62, and is configured so that light from the light emitter 61 is received by the light receiver 62. For example, the light emitter 61 and the light receiver 62 are installed so that optical axes thereof extend in the vertical direction. Two pairs of light emitters 61 and light receivers 62 are installed. When the wafer W held by the upper pick 52a passes between the light emitter 61 and the light receiver 62, four horizontal positions on an edge of the wafer W are measured. The position measurer 60 is provided at least in front of the gate valve 21a (the gate 22a), but may also be provided in front of the gate valve 21b (the gate 22b) of the load lock module 20b.

When the atmospheric transfer robot 50 transfers the wafer W to the load lock module 20a, the wafer W held by the upper pick 52a passes between the light emitter 61 and the light receiver 62. At this time, the position measurer 60 measures the horizontal position of the wafer W using the light emitted from the light emitter 61 toward the light receiver 62. A measurement result obtained by the position measurer 60 are output to a controller 200, which will be described later. The controller 200 controls the atmospheric transfer robot 50 based on the measurement result, and adjusts the horizontal position of the wafer W, for example, a center position of the wafer W. The controller 200 also detects whether or not the wafer W is on the upper pick 52a.

### Vacuum Part 11

Next, a configuration of the vacuum part 11 will be described. The vacuum part 11 includes a transfer module 70 as a first transfer module, and a plurality of, for example, six, processing modules 90.

The transfer module 70 includes a housing 71 having, for example, a polygonal shape in a plan view. An interior of the housing 71 is maintained in the vacuum atmosphere. The plurality of (for example, six) processing modules 90 are arranged side by side on both side surfaces of the housing 71 in a positive X-axis direction via gates 73 each having a gate valve 72. The two load lock modules 20a and 20b are arranged side by side on a side surface of the housing 71 in the negative Y-axis direction via the gates 24a and 24b having the gate valves 23a and 23b.

A vacuum transfer robot 80 serving as a first transfer robot for transferring the wafers W is provided inside the transfer module 70. As shown in FIG. 3, the vacuum transfer robot 80 includes an articulated transfer arm 81. A tip of the transfer arm 81 includes an upper pick 82a serving as a first pick and a lower pick 82b serving as a first pick, which are provided in two stages. The upper pick 82a has two plate portions. Six holding pads 83a are provided at each of two locations on a surface of each plate, that is, at four locations on the upper pick 82a. The number of holding pads 83a is not limited thereto. Three or more holding pads may be provided at each location at which one wafer W is held. Each holding pad 83a is made of a material having a high coefficient of friction with respect to the wafer W, such as elastomer or the like, and is configured to support the wafer W by a frictional force. The holding pads 83a prevent the wafer W supported by the upper pick 82a from shifting. The upper pick 82a is configured to collectively hold four wafers W. The lower pick 82b has a configuration similar to that of the upper pick 82a, and is configured to be capable of collectively holding four wafers W by holding pads 83b. A specific arrangement of the four wafers W held by the upper pick 82a and a specific arrangement of the four wafers W held by the lower pick 82b will be described later. The transfer arm 81 is configured to be capable of move each of the upper pick 82a and the lower pick 82b in the vertical and horizontal directions. The vacuum transfer robot 80 transfers the wafers W between the load lock modules 20a and 20b and the six processing modules 90.

As shown in FIG. 1, the processing module 90 includes a chamber 91 configured such that an interior thereof is hermetically sealed. The chamber 91 has, for example, a rectangular shape in a plan view.

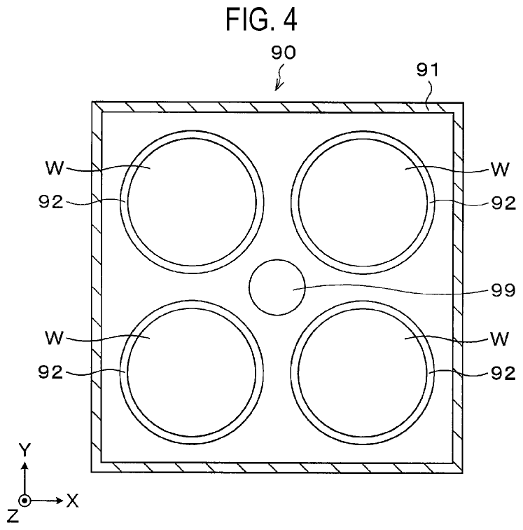

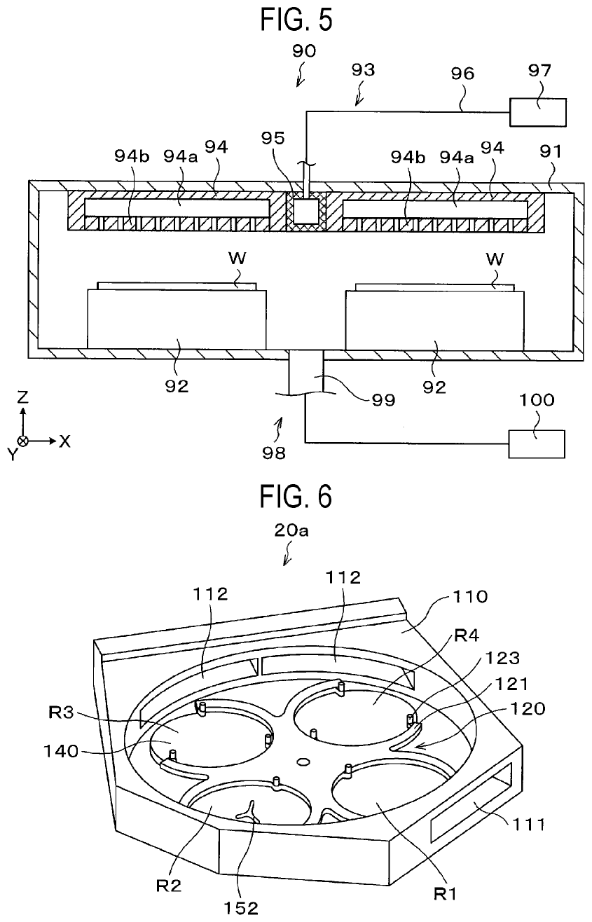

As shown in FIGS. 4 and 5, a plurality of, for example, four, stages 92 on which the wafers W are placed are provided inside the chamber 91. The four stages 92 are arranged concentrically at equal intervals, that is, at 90-degree intervals. Adjacent stages 92 are arranged at narrow intervals (hereinafter referred to as a “narrow pitch”). A specific arrangement of the four wafers W placed on the four stages 92 at such a narrow pitch, which will be described later, is the same as the arrangement of the four wafers W held by the upper pick 82a or the lower pick 52b of the vacuum transfer robot 80 described above. Each of the four stages 92 has the same configuration, and places the wafer W on an upper surface thereof, which is a placement surface. Each stage 92 functions as a susceptor. A temperature control mechanism (not shown) for adjusting a temperature of the wafer W is provided inside each stage 92.

Lifting pins (not shown) are provided to penetrate the stage 92. The lifting pins are configured to be movable in the vertical direction while supporting the wafer W. By the lifting pins, the wafer W may be delivered between the stage 92 and the vacuum transfer robot 80.

A gas supply 93 that supplies a processing gas into the chamber 91 is provided at an upper portion of the chamber 91. The gas supply 93 includes four shower heads 94, a gas branch portion 95, a gas supply pipe 96, and a gas source 97.

The four shower heads 94 are provided on a ceiling surface of the chamber 91 so as to face the four stages 92, respectively. A space 94a is formed inside the shower head 94. A lower surface of the shower head 94 constitutes a shower plate 94b. The shower plate 94b has a plurality of supply holes that penetrate the shower plate 94b in a thickness direction.

The gas branch portion 95 is connected to the four shower heads 94 and is provided in common to the four shower heads 94. The gas branch portion 95 is arranged at the center of the four shower heads 94 and above an exhaust pipe 99 (to be described later). The gas branch portion 95 is in communication with the gas source 97 via the gas supply pipe 96. The gas source 97 is configured to be capable of supply the processing gas for processing the wafer W.

In the gas supply 93, the processing gas from the gas source 97 is branched at the gas branch portion 95, supplied to the four shower heads 94, and then supplied to the wafer W placed on the stage 92 via the space 94a and the shower plate 94b of the shower head 94.

An exhauster 98 that exhausts the interior of the chamber 91 is provided at a lower portion of the chamber 91. The exhauster 98 includes an exhaust pipe 99 and an exhaust mechanism 100. The exhaust pipe 99 is arranged at the center of the four stages 92 on a bottom surface of the chamber 91. In other words, the exhaust pipe 99 is arranged below the gas branch portion 95. The exhaust mechanism 100 exhausts the interior of the chamber 91 via the exhaust pipe 99. In the exhauster 98, the interior of the chamber 91 is exhausted by the exhaust mechanism 100, so that the interior of the chamber 91 may be maintained in the vacuum atmosphere at a desired vacuum level.

The processing module 90 having the above configuration processes four wafers W in a collective manner under the vacuum atmosphere. Examples of processing performed under the vacuum atmosphere may include etching, plasma processing such as film formation or diffusion, chemical oxide removal, heat treatment, and the like.

### Load Lock Modules 20a and 20b

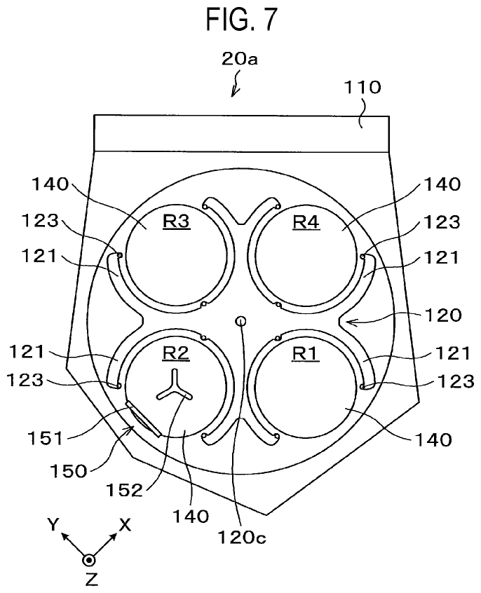

Next, a configuration of each of the load lock modules 20a and 20b will be described. The load lock modules 20a and 20b have a configuration that is axisymmetric with respect to the Y axis. In the following description, FIGS. 6 to 8 show the load lock module 20a.

As shown in FIGS. 6 to 8, each of the load lock modules 20a and 20b includes a chamber 110 whose interior is kept airtight. The chamber 110 has, for example, a polygonal shape in a plan view.

A loading/unloading port 111 for the wafer W is formed on a side surface of the chamber 110 facing the atmospheric part 10. The loading/unloading port 111 communicates with the gates 22a and 22b. The upper pick 52a and the lower pick 52b of the atmospheric transfer robot 50 sequentially pass through the gates 22a and 22b and the loading/unloading port 111. A loading/unloading port 112 for the wafer W is formed on a side surface of the chamber 110 facing the vacuum part 11. The loading/unloading port 112 communicates with the gates 24a and 24b. The upper pick 82a and the lower pick 82b of the vacuum transfer robot 80 sequentially pass through the gates 24a and 24b and the loading/unloading port 112.

A gas supply (not shown) for supplying a gas and an exhauster (not shown) for discharging the gas are connected to the chamber 110. An internal atmosphere of the chamber 110 may be switched between the atmospheric environment and the vacuum atmosphere by the gas supply and the exhauster. That is, each of the load lock modules 20a and 20b is configured to appropriately transfer the wafer W between the loader module 30 kept in the atmospheric environment and the transfer module 70 kept in the vacuum atmosphere.

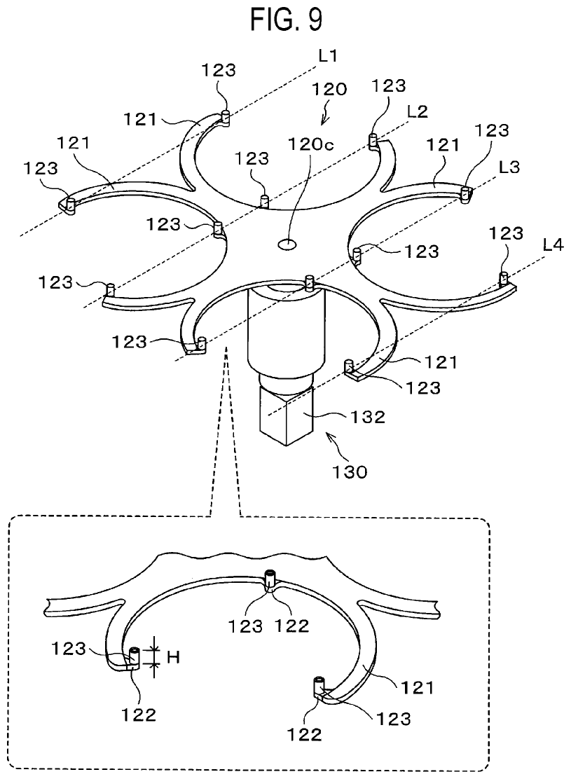

A rotary plate 120 serving as a rotary support capable of supporting four wafers W is provided inside the chamber 110. As shown in FIG. 9, the rotary plate 120 has four arms 121 formed integrally with each other. The four arms 121 are arranged at equal intervals in a circumferential direction of the rotary plate 120, that is, at 90-degree intervals as viewed from a center 120c of the rotary plate 120. Each arm 121 has a substantially arc-like shape in a plan view, for example, an approximately three-quarter annular (approximately U-shaped) shape with a diameter larger than that of the wafer W. When viewed from above, the arms 121 accommodate and support the wafers W so as to surround the wafers W therein. Each arm 121 is arranged such that an opening of the arc faces radially outward.

Since the rotary plate 120 has a shape in which a radially outer side of each arm 121 is cut out as described above, it is possible to reduce a turning radius of the rotary plate 120. Therefore, it is possible to reduce a size of each of the load lock modules 20a and 20b.

Each arm 121 is provided with a plurality of, for example, three, support portions 122 formed to protrude inward. Each support portion 122 is provided with a fixed support pin 123 that supports the wafer W while being in contact with the wafer W. The fixed support pin 123 does not move up and down and is fixed to the arm 121. The three fixed support pins 123 (the three support portions 122) are arranged at equal intervals in an outer periphery of the wafer W the circumferential direction.

Specifically, as shown in FIG. 9, the plurality of fixed support pins 123 on the rotary plate 120 are arranged along any one of a plurality of imaginary lines L1 to L4. The plurality of imaginary lines L1 to L4 extend perpendicularly toward the loading/unloading port 112. A width between the imaginary lines L1 and L2, and a width between the imaginary lines L3 and L4 are set to be larger than a width of one plate portion of the upper pick 82a and the lower pick 82b of the vacuum transfer robot 80, but smaller than an opening width of the loading/unloading port 112. This makes it possible to reduce a size of the rotary plate 120 while preventing interference with the pick of the vacuum transfer robot 80 which may collectively transfer the plurality of wafers.

The fixed support pin 123 is provided to protrude upward from an upper surface of the arm 121. A distance from the upper surface of the arm 121 to the tip of the fixed support pin 123, that is, a protruding height H of the fixed support pin 123, is greater than a thickness of the upper pick 52a and the lower pick 52b of the atmospheric transfer robot 50 and is also greater than a thickness of the upper pick 82a and the lower pick 82b of the vacuum transfer robot 80. Therefore, when the wafer W is delivered between the fixed support pin 123 and the picks 52a, 52b, 82a, and 82b as described below, the picks 52a, 52b, 82a, and 82b do not interfere with the fixed support pin 123, and the like.

Further, since the arm 121 has a substantially arc-like shape and the fixed support pins 123 are provided inward of the arm 121, the wafer W may be delivered between the fixed support pins 123 and the support pins 152 of the orienter 150 as will be described later. Similarly, the wafer W may be delivered between the fixed support pins 123 and the stage 140 as will be described later.

An upper tip of the fixed support pin 123 is approximately sharpened so as to be in point-contact with the wafer W. Further, the fixed support pins 123 are made of a material such as elastomer or the like having a high coefficient of friction with respect to the wafer W, and are configured to support the wafer W by a frictional force. The fixed support pins 123 prevent the wafer W supported on the rotary plate 120 from being shifted. With this configuration, the three fixed support pins 123 on each arm 121 horizontally support one wafer W.

The rotary plate 120 is configured to be capable of support four wafers W at equal intervals in the circumferential direction by four arms 121. A specific arrangement of the four wafers W supported by the rotary plate 120, which will be described later, is the same as the arrangement of the four wafers W held by the upper pick 82a or the lower pick 52b of the vacuum transfer robot 80 described above, and is also the same as the arrangement of the four wafers W placed on the four stages 92 of the processing module 90.

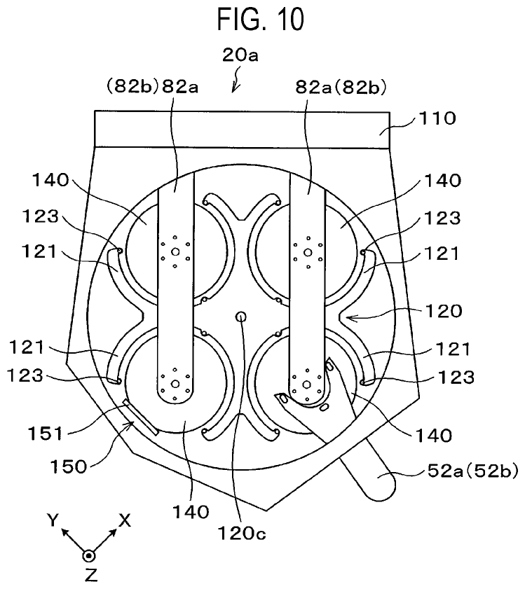

As shown in FIG. 10, all of the fixed support pins 123 are arranged at positions where the upper pick 52a or the lower pick 52b does not interfere with the fixed support pins 123 when the atmospheric transfer robot 50 transfers the wafer W to the fixed support pins 123. The upper pick 52a or the lower pick 52b moves in the vertical direction to transfer the wafer W to the fixed support pins 123. In other words, at this time, the fixed support pins 123 do not move in the vertical direction.

Similarly, all of the fixed support pins 123 are arranged at positions where the upper pick 82a or the lower pick 82b does not interfere with the fixed support pins 123 when the vacuum transfer robot 80 transfers the wafer W to the fixed support pins 123. The upper pick 82a or the lower pick 82b moves in the vertical direction to transfer the wafer W to the fixed support pins 123. In other words, at this time, the fixed support pins 123 do not move in the vertical direction.

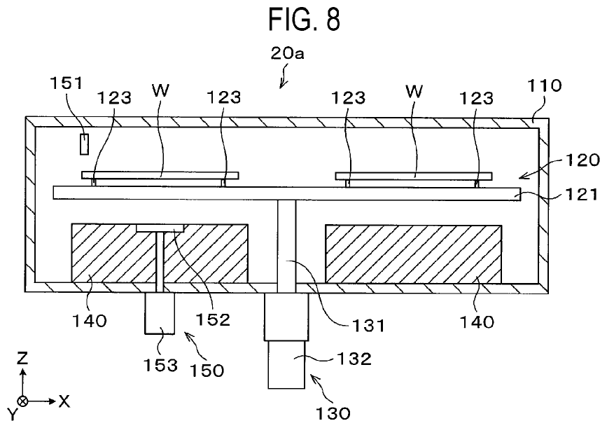

As shown in FIGS. 8 and 9, a drive mechanism 130 configured to drive the rotary plate 120 in a rotational direction is provided at the center 120c of the lower surface of the rotary plate 120. In other words, the rotary plate 120 is configured to be rotatable around the center 120c as a rotation axis. A configuration of the drive mechanism 130 is optional. For example, the drive mechanism 130 includes a shaft 131 and a drive 132. The shaft 131 is provided inside the chamber 110 to support a lower surface of the rotary plate 120. The drive 132 is provided outside the chamber 110 and attached to the shaft 131. The drive 132 incorporates, for example, a motor (not shown) and drives the rotary plate 120 in the rotational direction via the shaft 131.

As shown in FIGS. 6 to 8, a plurality of, for example, four, stage regions R1 to R4, are provided below the rotary plate 120 around the center 120c of the rotary plate 120. The four stage regions R1 to R4 are arranged at equal intervals in the circumferential direction of the rotary plate 120, that is, at 90-degree intervals when viewed from the center 120c of the rotary plate 120. When the rotary plate 120 rotates to a specific position, the four stage regions R1 to R4 are arranged below the four arms 121. Further, the stage region R1 is provided near the loading/unloading port 111, the stage region R2 is provided between the loading/unloading port 111 and the loading/unloading port 112, and the stage regions R3 and R4 are provided near the loading/unloading port 112.

Each of the stage regions R1 to R4 is provided with the stage 140. For example, a diameter of the stage 140 is smaller than an inner diameter of the arm 121.

An orienter 150 is provided in the stage region R2 to control an orientation of the notch of the wafer W relative to the rotary plate 120. The orienter 150 includes a notch detector 151, support pins 152, and a drive mechanism 153. The orienter 150 is provided in at least the load lock module 20a, but may also be provided in the load lock module 20b.

The notch detector 151 is provided above the rotary plate 120. The notch detector 151 uses, for example, a line sensor, to detect a position of the notch of the wafer W supported by the support pins 152.

The support pins 152 are provided to penetrate through the stage 140. Tips of the support pins 152 are embedded in an upper surface of the stage 140. The support pins 152 are configured to be capable of support the wafer W at their tips. In the illustrated example, the tips of the support pins 152 are configured to be capable of support the wafer W at three points. A shape of the tips is not limited thereto and may be any shape as long as the tips are able to support the wafer W.

The drive mechanism 153 is provided outside the chamber 110 to support the support pins 152. The drive mechanism 153 is configured to be capable of drive the support pins 152 in the rotational direction and to move the support pins 152 in the vertical direction. With this configuration, the support pins 152 are configured to be capable of move in the vertical direction between the upper surface of the stage 140 and above the stage 140, and are further configured to be capable of rotate in the rotational direction above the stage 140. Further, the arms 121 of the rotary plate 120 provided above the support pins 152 have a substantially arc-like shape, and the fixed support pins 123 are provided inside the arms 121, so that the wafer W may be delivered between the support pins 152 and the fixed support pins 123.

In the orienter 150, the wafer W supported by the support pins 152 is moved above the rotary plate 120, and then the position of the notch of the wafer W is detected by the notch detector 151 while rotating the wafer W. Thereafter, the wafer W is rotated so that the notch of the wafer W is positioned at an appropriate position, and the orientation of the notch is controlled.

### Controller 200

As shown in FIG. 1, the wafer processing apparatus 1 includes at least one controller 200. The controller 200 processes computer-executable instructions that cause the wafer processing apparatus 1 to execute various processes described herein. The controller 200 may be configured to control individual constituent elements of the wafer processing apparatus 1 to execute various processes described herein. In one embodiment, a portion or the entirety of the controller 200 may be included in the wafer processing apparatus 1. The controller 200 may include a processor, a memory, and a communication interface. The controller 200 may be implemented by, for example, a computer. The processor may be configured to read, from the memory, a program that provides logic or routines that enable various control operations to be performed, and may be configured to execute the read program to perform the various control operations. This program may be stored in the memory in advance or may be acquired via a medium H when needed. The acquired program is stored in the memory and is read from the memory and executed by the processor. The medium H may be any of various computer-readable storage media or a communication line connected to the communication interface. The storage medium may be a transitory storage medium or non-transitory storage medium. The processor may be a CPU (Central Processing Unit) or one or more circuits. The memory may include a RAM (Random Access Memory), a ROM (Read Only Memory), an HDD (Hard Disk Drive), an SSD (Solid State Drive), or a combination thereof. The communication interface may communicate with the wafer processing apparatus 1 via a communication line such as a LAN (Local Area Network) or the like.

### First Embodiment: Wafer Processing Method

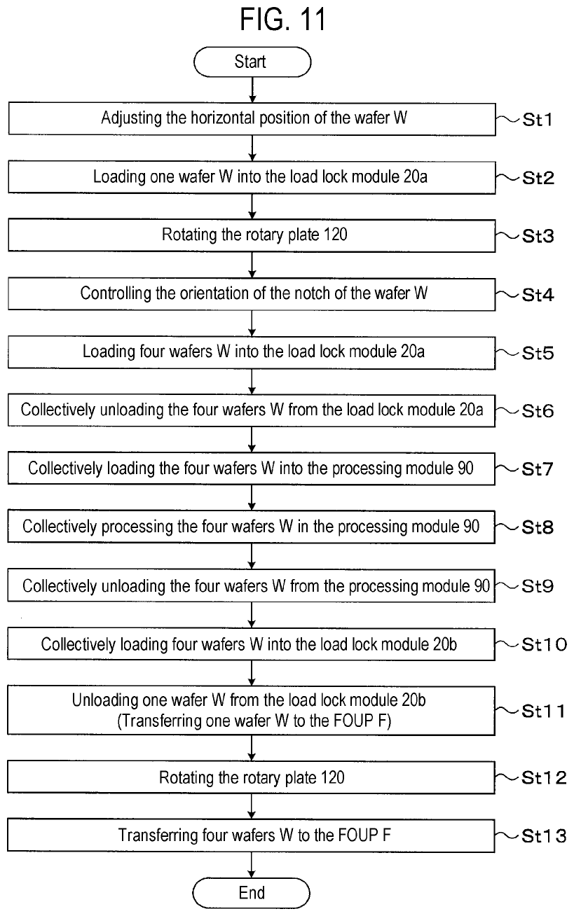

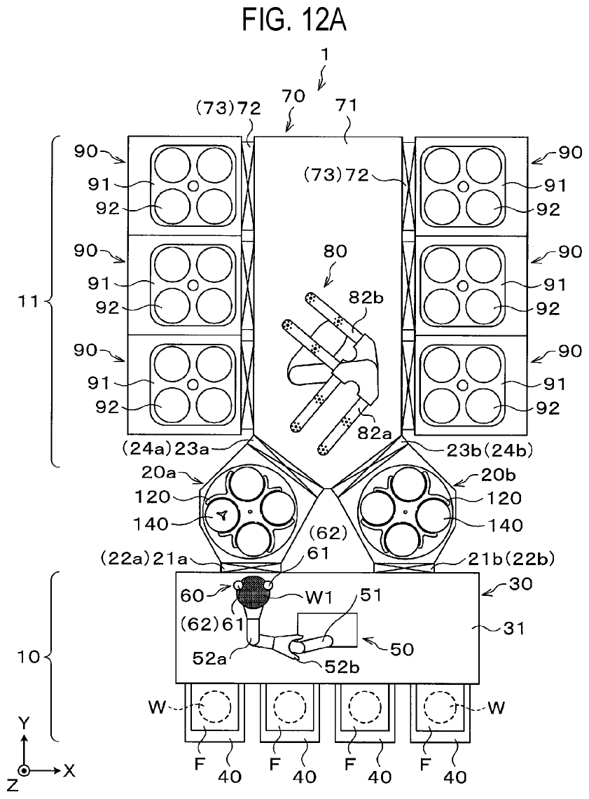

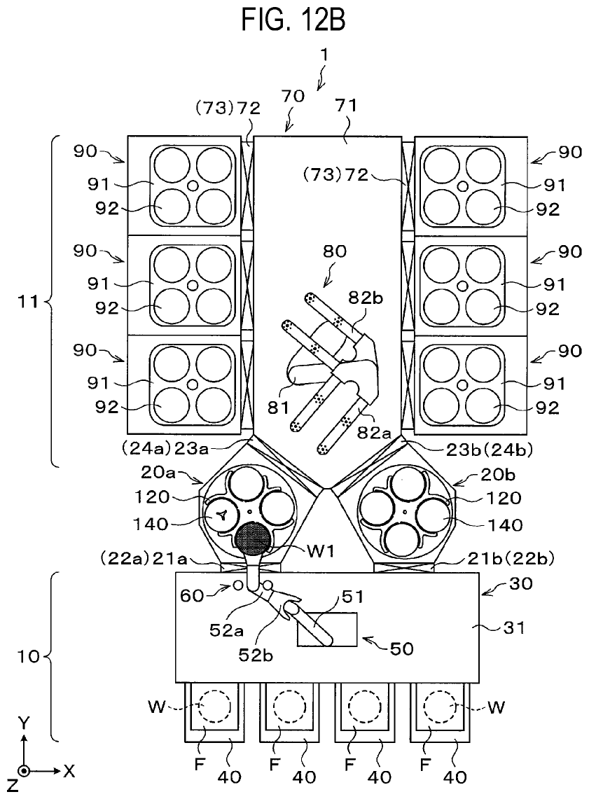

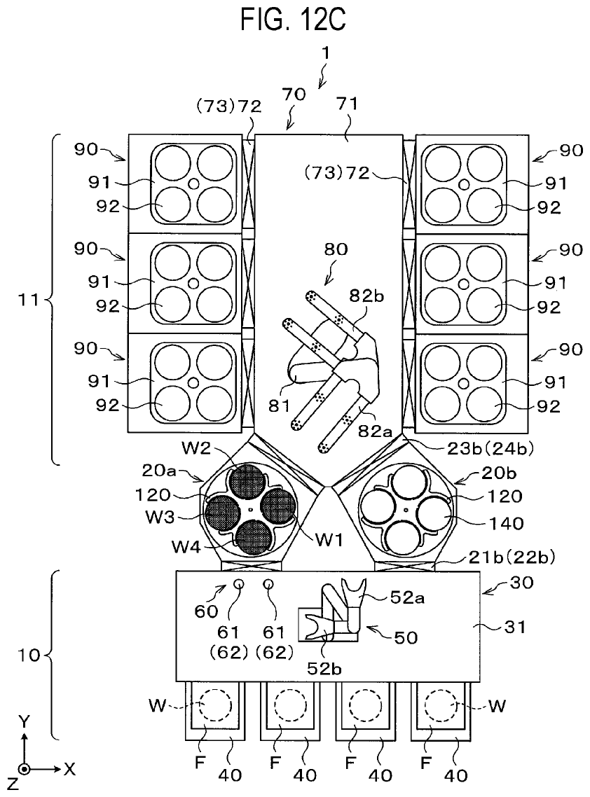

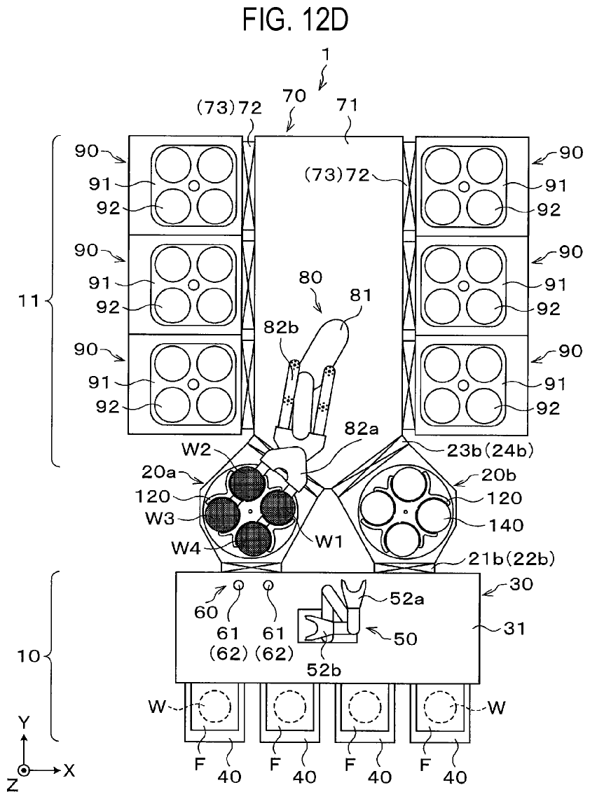

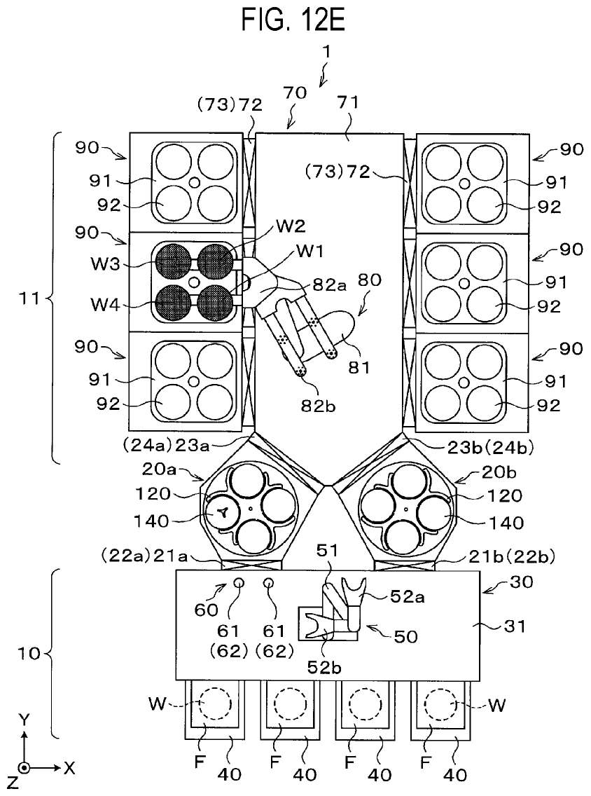

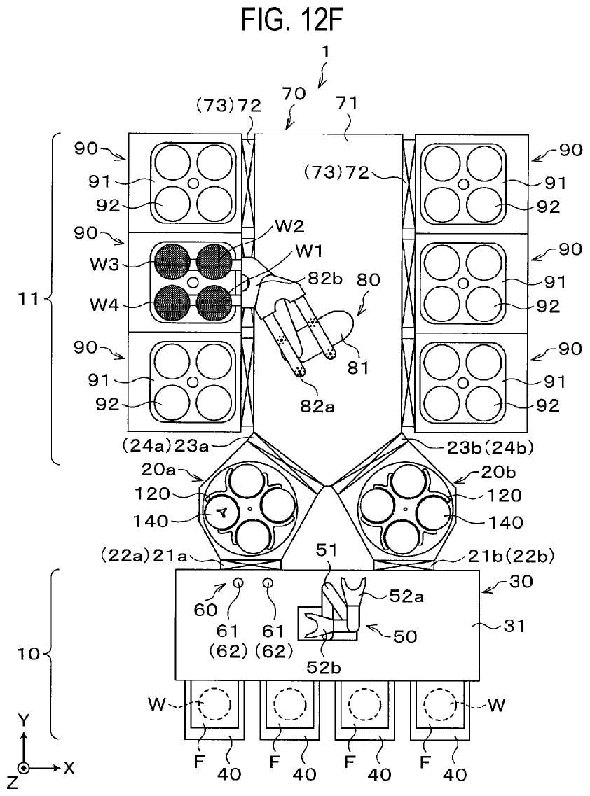

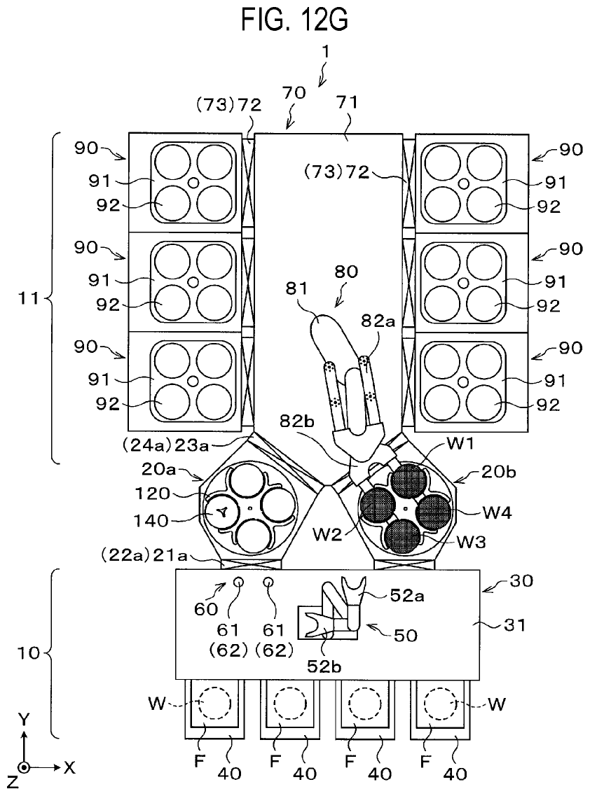

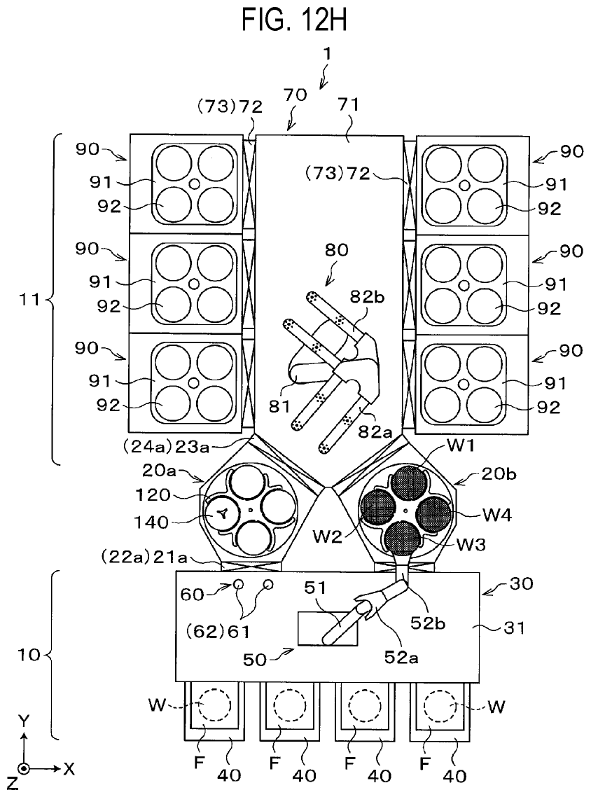

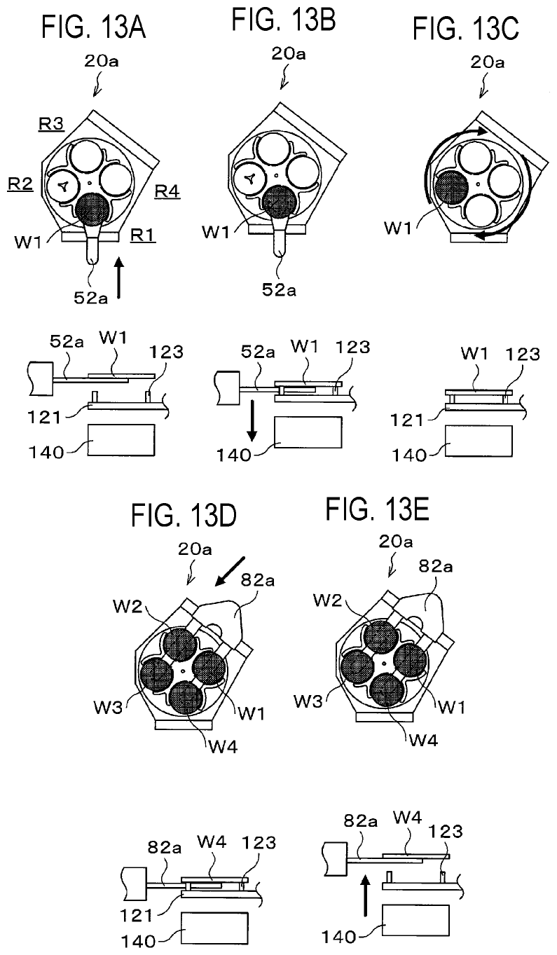

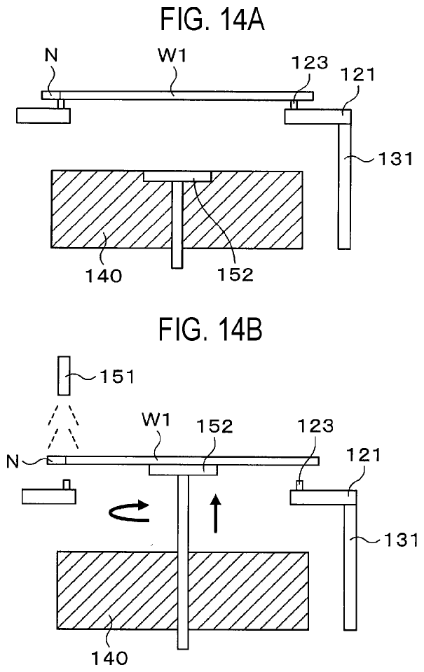

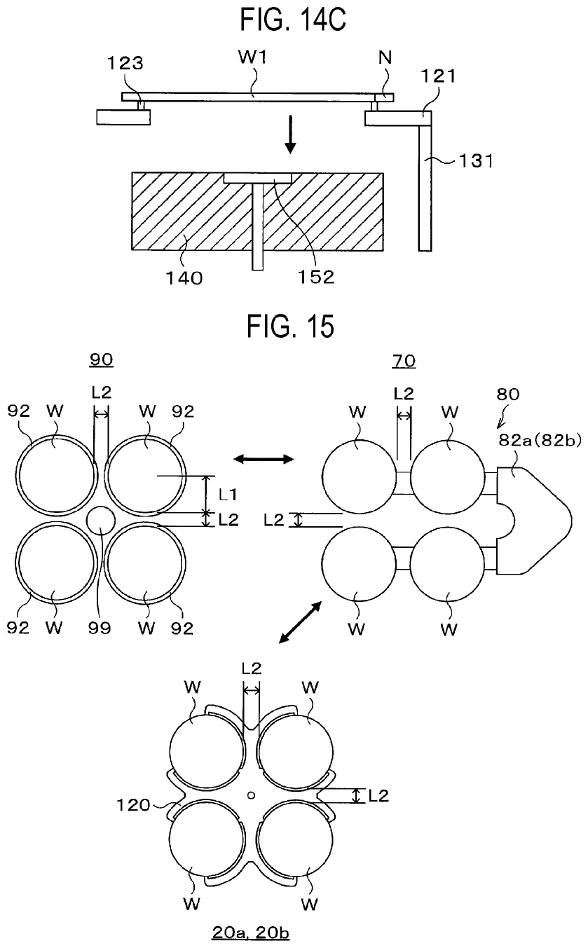

Next, the wafer processing performed by the wafer processing apparatus 1 configured as described above will be described. In the wafer processing, operations of individual constituent elements of the wafer processing apparatus 1 are controlled by the controller 200. FIG. 11 is a flow chart showing major operations of the wafer processing. FIGS. 12A to 12H are explanatory diagrams showing the major operations of the wafer processing performed in the wafer processing apparatus 1. FIGS. 13A to 13E are explanatory diagrams showing major operations of wafer transfer in the load lock module 20a. FIGS. 14A to 14C are explanatory diagrams showing major operations of notch orientation control for the wafer W in the orienter 150 of the load lock module 20a.

First, the FOUP F accommodating the plurality of wafers W is placed on the load port 40. Next, under the atmospheric environment, a first wafer W1 is taken out from the FOUP F by the upper pick 52a of the atmospheric transfer robot 50 and is transferred to the load lock module 20a. At this time, as shown in FIG. 12A, before the upper pick 52a passes through the gate 22a, the position measurer 60 measures the horizontal position of the wafer W1 held by the upper pick 52a. The measurement result obtained by the position measurer 60 is output to the controller 200. The controller 200 controls the atmospheric transfer robot 50 based on the measurement result to adjust the horizontal position of the wafer W supported by the upper pick 52a, for example, the center position of the wafer W (Operation St1 in FIG. 11).

Next, the gate valve 21a is open, and the upper pick 52a holding the first wafer W1 is moved into the load lock module 20a as shown in FIGS. 12B and 13A. At this time, the rotary plate 120 is arranged so that the four arms 121 are positioned above the stage regions R1 to R4. The wafer W1 held by the upper pick 52a is then positioned above the arm 121 corresponding to the stage region R1.

Next, as shown in FIG. 13B, the upper pick 52a is lowered, and the first wafer W1 is delivered from the upper pick 52a to the fixed support pins 123 of the arm 121. At this time, since the horizontal position of the wafer W has been adjusted in Operation St1, the first wafer W1 is delivered to an appropriate position relative to the fixed support pins 123. Further, since the protruding height H of the fixed support pins 123 is greater than the thickness of the upper pick 52a as described above, the upper pick 52a does not interfere with the first wafer W1 and the arm 121 even after delivering the first wafer W1 to the fixed support pins 123. In this manner, the first wafer W1 is loaded from the atmospheric transfer robot 50 into the load lock module 20a (Operation St2 in FIG. 11). Thereafter, the upper pick 52a is retracted from the load lock module 20a.

Next, as shown in FIG. 13C, the rotary plate 120 is rotated clockwise by 90 degrees to arrange the first wafer W1 above the stage region R2 (Operation St3 in FIG. 11).

Next, in the stage region R2, the orienter 150 controls the orientation of the notch position of the first wafer W1 (Operation St4 in FIG. 11). Further, the atmospheric transfer robot 50 transfers a second wafer W2 to a position corresponding to the stage region R1 in the load lock module 20a (Operations St1 and St2 in FIG. 11). The notch orientation control for the first wafer W1 and the transfer of the wafer W2 are performed in parallel. This improves throughput of the wafer processing. The transfer of the wafer W2 is similar to the transfer of the first wafer W1 in Operations St1 and St2.

In Operation St4, first, before controlling the position of the notch N of the first wafer W1, the support pins 152 of the orienter 150 are arranged on the upper surface of the stage 140 as shown in FIG. 14A.

Next, as shown in FIG. 14B, the support pins 152 are raised, and the first wafer W1 is delivered from the arm 121 to the support pins 152. The support pins 152 are positioned so that the first wafer W1 is spaced apart upward from the arm 121. Then, the notch detector 151 detects the position of the notch N of the first wafer W1 while rotating the support pins 152 and the first wafer W1. Thereafter, based on a detection result obtained by the notch detector 151, the drive mechanism 153 is controlled to rotate the first wafer W1 so that the notch N of the first wafer W1 is located at an appropriate position, thereby controlling the orientation of the notch N.

Next, as shown in FIG. 14C, the support pins 152 are lowered, and the first wafer W1 is delivered from the support pins 152 to the arm 121. The support pins 152 are arranged on the upper surface of the stage 140.

By repeatedly performing Operations St1 to St4 above for the second wafer W2, a third wafer W3, and a fourth wafer W4, the four wafers W1 to W4 are loaded into the load lock module 20a as shown in FIG. 12C (Operation St5 in FIG. 11).

Next, the gate valve 21a is closed. The interior of the load lock module 20a is sealed and depressurized, and is kept in the vacuum atmosphere. Thereafter, the gate valve 23a is open, and the interior of the load lock module 20a and the interior of the transfer module 70 are brought into communication with each other.

Next, as shown in FIGS. 12D and 13D, the upper pick 82a of the vacuum transfer robot 80 enters the interior of the load lock module 20a. The upper pick 82a is arranged between the four wafers W1 to W4 supported by the fixed support pins 123 and the arm 121. Since the protruding height H of the fixed support pins 123 is greater than the thickness of the upper pick 82a as described above, the upper pick 82a does not interfere with the four wafers W1 to W4 and the arm 121.

Next, as shown in FIG. 13E, the upper pick 82a is raised, and the four wafers W1 to W4 are delivered collectively to the upper pick 82a from the fixed support pins 123. Thereafter, the upper pick 82a is retracted from the load lock module 20a, and the four wafers W1 to W4 are unloaded collectively from the load lock module 20a (Operation St6 in FIG. 11).

Next, the gate valve 72 is open, and the upper pick 82a holding the four wafers W1 to W4 is moved into the processing module 90 as shown in FIG. 12E. The upper pick 82a is arranged so that the four wafers W1 to W4 are positioned above four stages 92. Then, the lifting pins (not shown) are used to place the four wafers W1 to W4 on the four stages 92. In this manner, the four wafers W1 to W4 are collectively loaded from the vacuum transfer robot 80 into the processing module 90 (Operation St7 in FIG. 11). Thereafter, the upper pick 82a is retracted from the processing module 90.

Next, the gate valve 72 is closed. In the processing module 90, the processing gas is supplied from the gas supply 93 into the chamber 91, and then the interior of the chamber 91 is exhausted by the exhauster 98. Then, the four wafers W1 to W4 are subjected to desired processing under the vacuum atmosphere (Operation St8 in FIG. 11).

Next, the gate valve 72 is open, and the lower pick 82b of the vacuum transfer robot 80 is moved into the processing module 90 as shown in FIG. 12F. Thereafter, the lifting pins (not shown) deliver the four wafers W1 to W4 from the four stages 92 to the lower pick 82b. Thereafter, the lower pick 82b is retracted from the processing module 90, and the four wafers W1 to W4 are collectively unloaded from the processing module 90 (Operation St9 in FIG. 11).

Next, the gate valve 23b is open, and the lower pick 82b holding the four wafers W1 to W4 is moved into the load lock module 20b as shown in FIG. 12G. At this time, the four wafers W1 to W4 are arranged above the arm 121 corresponding to the stage regions R1 to R4.

Next, the lower pick 82b is lowered, and the four wafers W1 to W4 are collectively delivered from the lower pick 82b to the fixed support pins 123 of the four arms 121. Since the protruding height H of the fixed support pins 123 is greater than the thickness of the lower pick 82b as described above, the lower pick 82b does not interfere with the four wafers W1 to W4 and the arms 121 even after delivering the four wafers W1 to W4 to the fixed support pins 123. In this way, the four wafers W1 to W4 are loaded from the vacuum transfer robot 80 into the load lock module 20b (Operation St10 in FIG. 11). Thereafter, the lower pick 82b is retracted from the load lock module 20b.

Next, the gate valve 23b is closed. The interior of the load lock module 20a is sealed and pressurized, and is kept in the atmospheric environment. Thereafter, the gate valve 21b is open, and the interior of the load lock module 20b and the interior of the loader module 30 are brought into communication with each other.

Next, as shown in FIG. 12H, the lower pick 52b of the atmospheric transfer robot 50 is moved into the load lock module 20b. The lower pick 52b is arranged between the third wafer W3 supported by the fixed support pins 123 at a position corresponding to the stage region R1 and the arm 121. Since the protruding height H of the fixed support pins 123 is greater than the thickness of the lower pick 52b as described above, the lower pick 52b does not interfere with the third wafer W3.

Next, the lower pick 52b is raised, and the third wafer W3 is delivered to the lower pick 52b from the fixed support pins 123. Thereafter, the lower pick 52b is retracted from the load lock module 20b, and the third wafer W3 is unloaded from the load lock module 20b. Subsequently, the lower pick 52b transfers the third wafer W3 to the FOUP F (Operation St11 in FIG. 11).

Next, the rotary plate 120 is rotated counterclockwise by 90 degrees to arrange the second wafer W2 above the stage region R1 (Operation St12 in FIG. 11).

By repeatedly performing Operations St11 to St10 above for the second wafer W2, the first wafer W1, and the fourth wafer W4, the four wafers W1 to W4 are sequentially transferred to the FOUP F (Operation St13 in FIG. 11). In this way, a series of wafer processing in the wafer processing apparatus 1 is completed.

### Effects of This Embodiment

According to this embodiment, in the wafer processing apparatus 1, four wafers W are collectively accommodated in each of the load lock modules 20a and 20b, are collectively transferred by the vacuum transfer robot 80, and are collectively processed in the processing module 90. In this case, the wafer processing apparatus 1 may be reduced in size compared to a case in which a single wafer W is transferred and processed. In addition, the throughput of the wafer processing in the wafer processing apparatus 1 may be improved.

Even in the related art, there is known an apparatus (hereinafter referred to as “the apparatus of the related art”) that collectively transfers and processes a plurality of wafers, such as the wafer processing apparatus disclosed in Patent Document 1 above. Specifically, the apparatus of the related art includes a loader module that transfers a single wafer under an atmospheric environment, a load lock module that accommodates a plurality of wafers, a transfer module that collectively transfers the plurality of wafers under a vacuum atmosphere, and a processing module that collectively processes the plurality of wafers under the vacuum atmosphere.

In the apparatus of the related art, the wafer is typically transferred to and from the stage of the load lock module using vertically-movable lifting pins provided in the stage. That is, when loading the wafer from the loader module into the load lock module, the transfer robot delivers the wafer to the lifting pins. Then, the lifting pins are lowered to place the wafer on the stage. When unloading the wafer from the load lock module to the transfer module, the wafer is delivered from the stage to the lifting pins, and then the lifting pins are raised to deliver the wafer to the transfer robot.

However, in the apparatus of the related art, when delivering the wafer using the lifting pins in the load lock module, misalignment occurs between the lifting pins and the wafer when the lifting pins come into contact with the wafer. This misalignment occurs in each of the wafers, particularly when the plurality of wafers are collectively transferred. In this case, when the wafers are subsequently transferred to the processing module, placement accuracy of each wafer on the stage of the processing module cannot be ensured, resulting in misalignment of the wafer on the stage. This makes it impossible to appropriately process the wafers. As a result, in order to appropriately process the wafers in the processing module, it may be necessary to provide a mechanism for correcting such a wafer misalignment in the processing module according to a processing process.

In this regard, according to this embodiment, in each of the load lock modules 20a and 20b, the rotary plate 120 includes the plurality of fixed support pins 123 that support the wafers W. When transferring the wafers W between each of the load lock modules 20a and 20b and the loader module 30, the atmospheric transfer robot 50 transfers the wafers W with respect to the fixed support pins 123. Similarly, when transferring the four wafers W between each of the load lock modules 20a and 20b and the transfer module 70, the vacuum transfer robot 80 transfers the four wafers W. At this time, the fixed support pins 123 do not move up and down but are fixed to the arm 121. Therefore, in this embodiment, when delivering the wafers W, it is not necessary to vertically move the fixed support pins 123 as in the related art. Accordingly, the contact of the fixed support pins 123 with the wafers W due to such a vertical movement is not generated. In other words, the wafers W may be transferred to each of the load lock modules 20a and 20b while minimizing the number of the contacts of the fixed support pins 123 with the wafers W. Therefore, it is possible to suppress the misalignment of the wafers that occurs in the apparatus of the related art described above, thereby improving the transfer accuracy of the wafers W. As a result, in the processing module 90, the four wafers W may be placed on the four stages 92 at appropriate positions. That is, the placement accuracy of the four wafers W on the four stages 92 may be improved, and the four wafers W may be processed appropriately.

Further, according to this embodiment, since the four wafers W may be placed at the appropriate positions on the four stages 92 in the processing module 90, there is no need to provide a wafer position correction mechanism in the processing module as in the apparatus of the related art. This makes it possible to simplify the wafer processing apparatus 1 and to reduce the cost of the apparatus.

In the apparatus of the related art, the misalignment of the wafer on the stage in the processing module has not been considered as a problem, and the improvement of the placement accuracy of the wafer on the stage has not been raised as an issue. In particular, when a plurality of wafers are transferred collectively, it is necessary to provide a transfer system that may ensure high positional accuracy for each of the plurality of wafers. However, it is difficult to ensure such positional accuracy in the apparatus of the related art. As a result, it is necessary to add a wafer position correction mechanism to the processing module.

Further, in the apparatus of the related art, when delivering the plurality of wafers in the load lock module, the same number of lifting pins as the number of wafers are required, and a drive mechanism is required for each of the multiple lifting pins to raise and lower them.

In this regard, according to this embodiment, the wafers W are transferred to and from the atmospheric transfer robot 50 or the vacuum transfer robot 80 without raising or lowering the fixed support pins 123 in each of the load lock modules 20a and 20b, thereby eliminating the need for the drive mechanism of the apparatus of the related art described above. This makes it possible to simplify the wafer processing apparatus 1 and to reduce the cost of the apparatus. Further, since the number of drive mechanisms may be reduced, it is possible to avoid problems caused by the drive mechanisms, and to improve maintenance capacity of each of the load lock modules 20a and 20b.

In other words, the wafer processing apparatus 1 according to this embodiment may ensure high positional accuracy in the medium to long term even when the plurality of wafers W are transferred collectively. When the multiple lifting pins are provided as in the apparatus of the related art, it is difficult to ensure the same lifting pin drive accuracy for multiple drive mechanisms in the medium to long term due to factors such as the influence of aging on motors and the quality of maintenance on the pin lifting mechanisms. However, the wafer processing apparatus 1 according to this embodiment may eliminate factors that cause wafer misalignment due to the lifting pins during the transfer process of transferring the wafers W to the processing module 90. Accordingly, even when the plurality of wafers W are transferred collectively, high positional accuracy may be ensured in the medium to long term.

In addition, in the apparatus of the related art, the wafers are transferred one by one from the loader module to the load lock module. Therefore, the plurality of wafers are accommodated in the load lock module by repeatedly performing the placement of the wafers on the stages of the load lock module from the transfer robot of the loader module and the rotation of the stage.

In this regard, according to this embodiment, the four wafers W are accommodated in each of the load lock modules 20a and 20b by repeatedly performing the placement of the wafers W on the fixed support pins 123 of the rotary plate 120 and the rotation of the rotary plate 120. That is, unlike the apparatus of the related art, the rotary plate 120 is rotated independently of the stage 140. The rotary plate 120 is simpler than the stage 140, and the drive mechanism 130 for driving the rotary plate 120 in the rotational direction does not need to be large. Therefore, it is possible to simplify the wafer processing apparatus 1, reduce the cost of the apparatus, and improve the throughput in the transfer process.

Further, the apparatus of the related art sometimes uses a magnetic levitation stage as the stage on which the wafer is placed. In such a case, a mechanism for magnetic levitation becomes large, which increases the size of the load lock module. As a result, the size of the apparatus of the related art also increases.

In this regard, according to this embodiment, there is no need to move the stage 140 in each of the load lock modules 20a and 20b, and there is no need to provide the magnetic levitation mechanism of the apparatus of the related art. Therefore, it is possible to simplify the wafer processing apparatus 1 and reduce the cost of the apparatus.

### Narrow Pitch Arrangement

Next, the arrangement of the four wafers W in each of the load lock modules 20a and 20b described above, the arrangement of the four wafers W in the transfer module 70, and the arrangement of the four wafers W in the processing module 90 will be described. FIG. 15 is an explanatory diagram showing the arrangement of the four wafers W.

As shown in FIG. 15, the arrangement of the four wafers W supported by the rotary plate 120, the arrangement of the four wafers W held by the upper pick 82a or the lower pick 52b of the vacuum transfer robot 80, and the arrangement of the four wafers W placed on the four stages 92 of the processing module 90 are the same. Therefore, when the four wafers W are transferred between each of the load lock modules 20a and 20b and the transfer module 70, or between the transfer module 70 and the processing module 90, it is possible to suppress misalignment of the four wafers W, thereby improving the transfer accuracy of the wafers W.

In each of the load lock modules 20a and 20b, the transfer module 70, and the processing module 90, the four wafers W are arranged at a narrow pitch. Specifically, as shown in Formula (1) below, when a radius of the wafer W is assumed to be L1 (hereinafter referred to as “wafer radius L1”), in the arrangement of the four wafers W, a distance L2 between adjacent wafers W (hereinafter referred to as “wafer-to-wafer distance L2”) is less than ½ of the radius L1. For example, when the wafer radius L1 is 150 mm, the wafer-to-wafer distance L2 is less than 75 mm and is set to, for example, 50 mm.

L2<L1×½ (1)

As a result of earnest research conducted by the present inventors, it was found that, when the four wafers W are arranged at a narrow pitch so as to satisfy Formula (1) above, the following effects may be obtained.

That is, according to this embodiment, since the four wafers W are supported at a narrow pitch on the rotary plate 120, the rotary plate 120 may be reduced in size, which reduces the size of each of the load lock modules 20a and 20b. Further, since the four wafers W held by the upper pick 82a or the lower pick 52b are arranged at a narrow pitch, the vacuum transfer robot 80 may be reduced in size, which reduces the size of the transfer module 70. In addition, since the four wafers W placed on the four stages 92 are arranged at a narrow pitch, the distance between adjacent stages 92 may be reduced, which reduces the size of the processing module 90. Therefore, it is possible to reduce the size of the wafer processing apparatus 1 as a whole.

Further, according to this embodiment, since the four wafers W are collectively transferred from the transfer module 70 to the processing module 90, there is no need to rotate the four stages 92 of the processing module 90. Therefore, a drive mechanism for rotating the four stages 92 is not required. In other words, the four stages 92 may be arranged at a narrow pitch at which a drive mechanism would not be arranged. Therefore, from such a viewpoint, it is possible to reduce the size of the processing module 90.

In the apparatus of the related art described above, the plurality of wafers are transferred in a collective manner. However, it is practically difficult to achieve the collective transfer of the plurality of wafers in the transfer module and the arrangement of the plurality of stages at the narrow pitch in the processing module. The reasons for this will be described below.

In the apparatus of the related art, when the plurality of wafers are transferred collectively from the transfer module to the processing module, the plurality of wafers needs to be placed at appropriate positions on the plurality of stages in the processing module. However, it is difficult to ensure the placement accuracy of the wafers on all of the stages. Therefore, from the viewpoint of ensuring such a wafer placement accuracy in the processing module, it is desirable to provide a position correction mechanism, such as a rotation mechanism or a movable mechanism, inside the processing module to ensure the wafer placement accuracy in the processing module.

However, in a case in which such a position correction mechanism is provided, the size of the processing module increases. In particular, in a case in which a gas supply process (supply of a processing gas) and an exhaust process (exhaust of the interior) needs to be performed in the processing module, the processing module is likely to become large. In other words, in the apparatus of the related art that collectively transfers the plurality of wafers, it is practically difficult to adopt narrow pitch arrangement of a plurality of stages unless the wafer placement accuracy in the processing module cannot be ensured. In other words, the wafer processing apparatus that collectively transfers the plurality of wafers has a problem in that it is difficult to achieve both the collective transfer of the plurality of wafers in the transfer module and the narrow pitch arrangement of the plurality of stages in the processing module.

In contrast, the present inventors have found that, in the collective transfer of the four wafers W in the transfer module 70, by applying the fixed support pins to the rotary plate 120 in each of the load lock modules 20a and 20b, it is possible to essentially achieve both the narrow pitch arrangement of the four stages 92 in the processing module 90 and the collective transfer of the plurality of wafers W in the transfer module 70.

Specifically, in the load lock module of the apparatus of the related art, the wafers are transferred using the lifting pins, and the stage is rotated. However, according to this embodiment, the rotary plate 120 is rotated independently of the stage 140. Further, the fixed support pins 123 provided on the rotary plate 120 do not move up and down to support the wafers W. By using the rotary plate 120 having such a configuration, it is possible to ensure the placement accuracy of the four wafers W on the four stages 92 as described above. Therefore, it is possible to implement both the collective transfer of the four wafers W in the transfer module 70 and the narrow pitch arrangement of the four stages 92 in the processing module 90, which have been difficult to implement such two issues in the apparatus of the related art.

The narrow pitch arrangement of the four stages 92 in the processing module 90 is particularly useful when a process requiring intake and exhaust of a gas, such as an etching process or a film formation process, is performed in the processing module 90.

As shown in FIGS. 4 and 5, the processing module 90 includes the gas supply 93 that supplies the processing gas into the chamber 91 and the exhauster 98 that discharges the gas from the chamber 91. Even when the four stages 92 are arranged at a narrow pitch as shown in FIG. 15, a space exists at the center of the four stages 92. The gas branch portion 95 of the gas supply 93 and the exhaust pipe 99 of the exhauster 98 are arranged at the center of the four stages 92. In this case, the gas branch portion 95, which is a gas supply component, and the exhaust pipe 99, which is an exhaust component, may be shared for the four wafers W placed on the four stages 92. As a result, the cost of the apparatus may be reduced compared to a case where the gas branch portion 95 and the exhaust pipe 99 are individually provided for each of the four wafers W.

In particular, the gas branch portion 95 of the gas supply 93 is arranged at the center of the four shower heads 94, which is useful in downsizing the processing module 90. In a case in which the gas branch portion is not be provided between the shower heads 94, the gas branch portion must be provided above the shower heads 94, which increases a height of the chamber 91 and makes it impossible to downsize the processing module 90.

Further, when the arrangement pitch of the four stages 92 is wide, distances between the gas branch portion 95 and the exhaust pipe 99 and the four wafers W placed on the four stages 92 increase, which affects a process performance for the four wafers W. In this regard, when the four stages 92 are arranged at a narrow pitch as in this embodiment (when Formula (1) above is satisfied), the distances between the gas branch portion 95 and the exhaust pipe 99 and the four wafers W are decreased, which makes it possible to improve the process performance for the four wafers W.

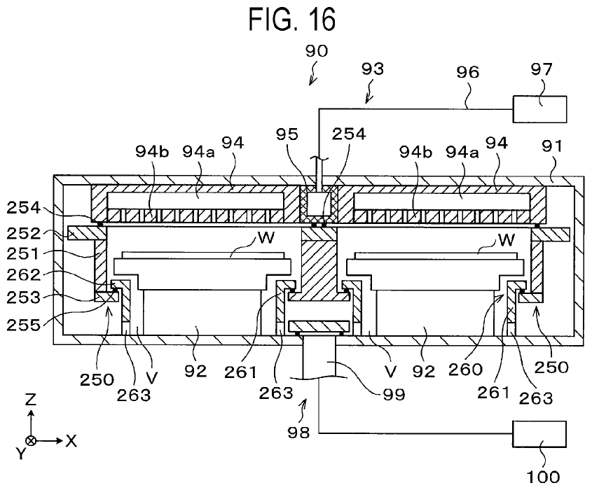

The configuration of the processing module 90 is not limited to this embodiment. For example, as shown in FIG. 16, in the processing module 90, a partition wall 250 may be provided on an outer periphery of the stage 92. The partition wall 250 is configured to be movable vertically by an elevating mechanism (not shown). The partition wall 250 includes four cylindrical portions 251 individually surrounding the four stages 92, upper flange portions 252 provided at upper ends of the cylindrical portions 251, and lower flange portions 253 provided at lower ends of the cylindrical portions 251. An inner diameter of the cylindrical portions 251 is set to be larger than a diameter of an outer surface of the stage 92, so that a gap is formed between the cylindrical portion 251 and the stage 92.

On an upper surface of the upper flange portion 252, a sealing member 254 such as a resin-made O-ring or the like is provided so as to correspond to each stage 92. The sealing member 254 airtightly seals a gap between the shower head 94 and the upper flange portion 252 when the upper flange portion 252 and the shower head 94 come into contact with each other by raising the partition wall 250. Further, a sealing member 255 such as a resin-made O-ring or the like is provided so as to correspond to each stage 92 on a protruding portion 262 of an inner wall 260 (to be described later). The sealing member 255 airtightly seals a gap between the lower flange portion 253 and the protruding portion 262 when the protruding portion 262 and the lower flange portion 253 come into contact with each other. The partition wall 250 is raised to bring the shower head 94 into contact with the sealing member 254, and further to bring the lower flange portion 253 into contact with the sealing member 255, so that a processing space S surrounded by the stage 92, the partition wall 250, and the shower head 94 is formed.

The inner wall 260 fixed to the bottom surface of the chamber 91 is provided around the outer periphery of the stage 92. The inner wall 260 includes a substantially cylindrical main body 261 and a protrusion 262 provided at an upper end of the main body 261 and protruding outward from the inner wall 260. The inner wall 260 is arranged to surround each individual stage 92. An inner diameter of the main body 261 of the inner wall 260 is set to be larger than an outer diameter of the stage 92, and an exhaust space V is formed between the inner wall 260 and the stage 92.

A plurality of slits 263 is formed at a lower end of the inner wall 260. The slits 263 are exhaust ports through which the processing gas is discharged. In this embodiment, the slits 263 are formed at approximately equal intervals along a circumferential direction of the inner wall 260.

The exhaust pipe 99 of the exhauster 98 is arranged on the bottom surface of the chamber 91, outside the partition wall 250 and the inner wall 260, and at the center of the four stages 92 as described above. The exhaust pipe 99 is provided in common to four inner walls 260. That is, the processing gas from four exhaust spaces V is discharged from the common exhaust pipe 99.

Even when the partition walls 250 and the inner walls 260 are provided in the processing module 90 as described above, the above-described effects described in connection with the narrow pitch arrangement of the four stages 92 may be obtained. In particular, since the rotation mechanism for the stages 92 is not provided inside the processing module 90, even when the partition walls 250, the inner walls 260, and the like are provided, a complex structure including the partition walls 250, the inner walls 260, and the like may be implemented at a narrow pitch. In addition, since the rotation mechanism for the stages 92 is not provided, a movement amount of the partition walls 250 may be minimized.

### Method of Adjusting Wafer Position

The wafer processing apparatus 1 of this embodiment includes the position measurer 60 provided inside the loader module 30, and the orienter 150 provided inside the load lock module 20a. The position measurer 60 and the orienter 150 are used to adjust a position of an unprocessed wafer W.

That is, in Operation St1, the position measurer 60 measures the horizontal position of the wafer W held by the atmospheric transfer robot 50. Based on such a measurement result, the horizontal position of the wafer W supported by the upper pick 52a, for example, the center position of the wafer W, is adjusted. Further, in Operation St4, the orienter 150 detects the notch position of the wafer W. Based on such a detection result, the notch orientation of the wafer W is controlled. Since the horizontal position adjustment for the wafer W in Operation St1 and the notch orientation control for the wafer W in Operation St4 are performed in this manner, the position of the unprocessed wafer W may be appropriately adjusted. As a result, the wafer W may be placed at an appropriate position on the stage 92 in the processing module 90, and the wafer W may be appropriately processed.

In the apparatus of the related art, the orienter is provided in the loader module. The orienter adjusts the horizontal position of the wafer and controls the notch orientation of the wafer.

In this regard, according to this embodiment, the orienter of the loader module in the apparatus of the related art may be omitted. This reduces the size of the wafer processing apparatus 1. On the other hand, in a case in which the orienter 150 is provided in the load lock module 20a as in this embodiment, the horizontal position of the wafer W cannot be adjusted in the load lock module 20a. Therefore, as in this embodiment, the position measurer 60 is provided in the loader module 30 to adjust the horizontal position of the wafer W.

Further, in the apparatus of the related art, the loader module or the load lock module may be deformed due to a temperature influence. In such a case, even if the horizontal position of the wafer is adjusted using the orienter of the loader module, the wafer may be misaligned when being transferred to the load lock module.

In this regard, according to this embodiment, the horizontal position of the wafer W is measured by the position measurer 60 immediately before the wafer W is transferred to the load lock module 20a. Therefore, the above-mentioned temperature influence may be minimized and the horizontal position of the wafer W relative to the load lock module 20a may be appropriately adjusted.

### Method of Controlling Notch Orientation of Wafer

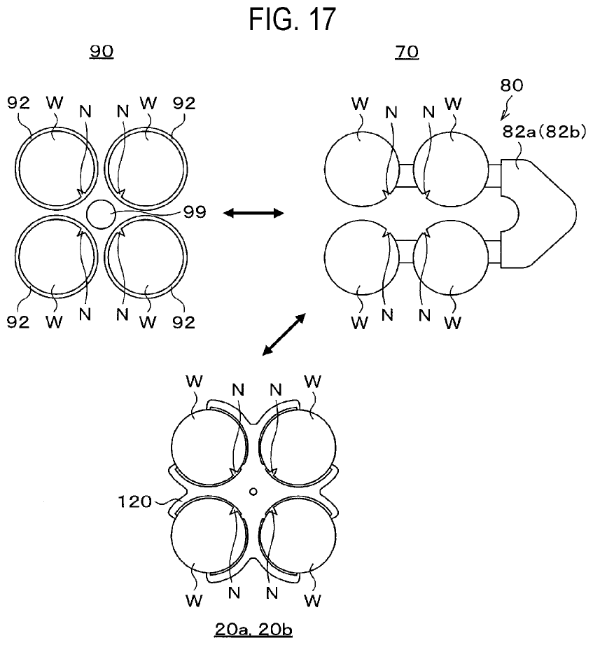

According to this embodiment, in Operation St4, the orienter 150 detects the notch position of the wafer W, and the notch orientation of the wafer W is controlled based on the detection result. In this case, as shown in FIG. 17, the notches N of the four wafers W supported on the rotary plate 120 may be positioned on sides (radially inward sides) facing the center 120c of the rotary plate 120. In such a case, the notches N of the four wafers W are positioned near the center even in the upper pick 82a of the vacuum transfer robot 80 and the four stages 92 of the processing module 90.

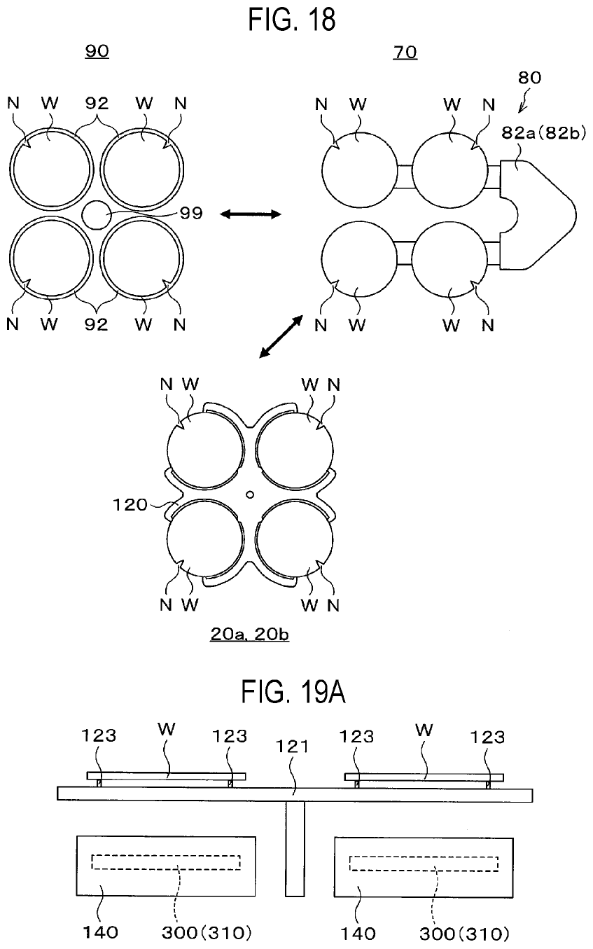

Alternatively, as shown in FIG. 18, the notches N of the four wafers W supported on the rotary plate 120 may be positioned on opposite sides (radially outward sides) of the center 120c of the rotary plate 120. In this case, the notches N of the four wafers W are also positioned on the opposite sides of the center even in the upper pick 82a of the vacuum transfer robot 80 and the four stages 92 of the processing module 90.

Regardless of whether the notches N of the four wafers W are positioned on the sides facing the center or on the opposite sides of the center, the four wafers W placed on the four stages 92 in the processing module 90 have symmetry. After the four wafers W are subjected to a desired processing in the processing module 90, whether or not the processing has been appropriately performed on the four wafers W may be analyzed. In this case, an analysis accuracy may be improved. In addition, even when analyzing a cause of occurrence of a trouble, an analysis accuracy may be improved.

### Second Embodiment

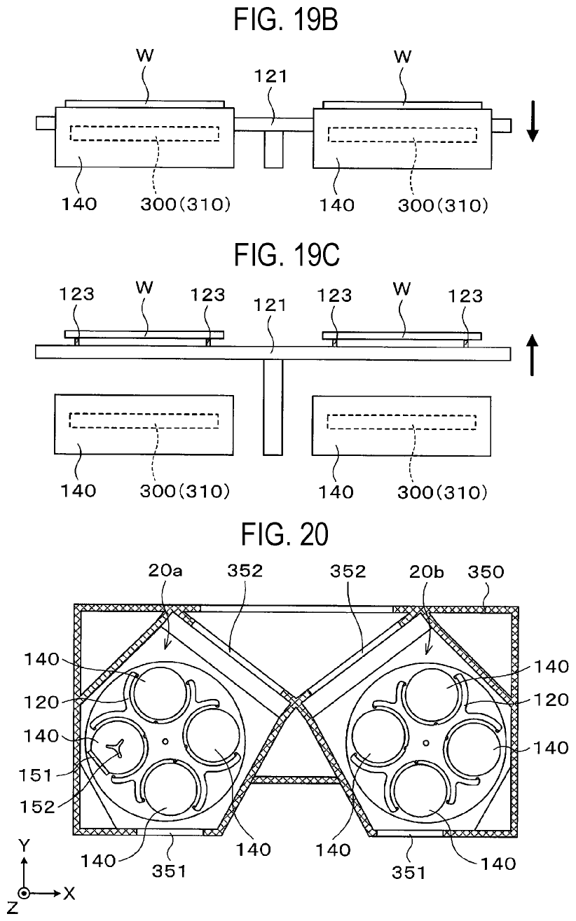

In each of the load lock modules 20a and 20b of the above-described embodiment, the stage 140 may be provided with a heat treatment mechanism. As shown in FIGS. 19A to 19C, for example, the stage 140 of the load lock module 20a is provided with a heating mechanism 300. In addition, for example, the stage 140 of the load lock module 20b is provided with a cooling mechanism 310. Notches are formed on the outer surface of the stage 140 of the load lock modules 20a and 20b at positions corresponding to the support portions 122 (the fixed support pins 123) of the rotary plate 120.

In each of the load lock modules 20a and 20b, the drive mechanism 130 is configured to be capable of driving the rotary plate 120 in the rotational direction as well as in the vertical direction. In other words, the rotary plate 120 is configured to be rotatable about the center 120c as a rotation axis and to be able to move in the vertical direction. The controller 200 also controls the drive mechanism 130 to adjust a vertical position of the rotary plate 120 relative to the stage 140.

In this case, the four wafers W are loaded into the load lock module 20a in Operation St5 as shown in FIG. 19A.

As shown in FIG. 19B, the rotary plate 120 is lowered, and the four wafers W held on the rotary plate 120 are delivered to the stage 140. At this time, since the notches are formed on the outer surface of the stage 140, the support portions 122 of the rotary plate 120 do not interfere with the stage 140. Further, since the arms 121 of the rotary plate 120 have a substantially arc-like shape and the fixed support pins 123 are provided inside the arms 121, the wafers W may be delivered between the stage 140 and the fixed support pins 123. Thereafter, the wafers W placed on the stage 140 are heated to a desired temperature by the heating mechanism 300.

Next, as shown in FIG. 19C, the rotary plate 120 is raised, and the four wafers W placed on the stage 140 are delivered to the rotary plate 120. Thereafter, in Operation St6, the four wafers W are collectively unloaded from the load lock module 20a.

When the four wafers W are processed in the processing module 90 in Operation St8, the four wafers W may be heated. Heating the four wafers W in the load lock module 20a as in this embodiment is so-called preheating for wafer processing in Operation St8. Therefore, a heating operation in Operation St8 may be omitted, which improves the throughput of the wafer processing.

As shown in FIG. 19A, in Operation St10, the four wafers W are collectively loaded into the load lock module 20b.

Next, as shown in FIG. 19B, the rotary plate 120 is lowered, and the four wafers W held on the rotary plate 120 are delivered to the stage 140. Thereafter, the wafers W placed on the stage 140 are cooled to a desired temperature by the cooling mechanism 310.

Next, as shown in FIG. 19C, the rotary plate 120 is raised, and the four wafers W placed on the stage 140 are delivered to the rotary plate 120. Thereafter, in Operation St11, one wafer W is unloaded from the load lock module 20b.

When the four wafers W are processed in the processing module 90 in Operation St8, the four wafers W may be heated. In such a case, the four wafers W need to be cooled before returning to the FOUP F. However, as in this embodiment, the four wafers W may be cooled in the load lock module 20b.

In the apparatus of the related art, a cooling module is provided in the loader module, and the wafers are cooled in the cooling module.

In this regard, according to this embodiment, the cooling mechanism 310 is provided on the stage 140 of the load lock module 20b. Therefore, the cooling module of the loader module in the apparatus of the related art may be omitted, which reduces the size of the wafer processing apparatus 1.

The heat treatment mechanism provided in each of the load lock modules 20a and 20b is not limited to that in this embodiment. For example, a heating mechanism may be provided in each stage 140 of the load lock modules 20a and 20b, or a cooling mechanism may be provided on each stage 140 of the load lock modules 20a and 20b.

### Third Embodiment

The wafer processing apparatus 1 according to the above-described embodiment is provided with two load lock modules 20a and 20b. The two load lock modules 20a and 20b may be integrated with each other as shown in FIG. 20. In such a case, the two chambers 110 are integrated to constitute a chamber 350. Further, an interior of the chamber 350 is partitioned to provide two load lock modules 20a and 20b. The chamber 350 may have any shape as long as it is configured to airtightly accommodate the two load lock modules 20a and 20b.

Two loading/unloading ports 351 are formed in a side surface of the chamber 350 in the negative Y-axis direction (on a side facing the loader module 30). The two loading/unloading ports 351 are formed so as to correspond to the two load lock modules 20a and 20b, respectively. The atmospheric transfer robot 50 transfers the wafers W to the load lock module 20a or 20b via the loading/unloading ports 351. Further, the loading/unloading ports 352 are formed in an inner sidewall of the chamber 350 in the positive Y-axis direction (on a side facing the transfer module 70) of the load lock modules 20a and 20b, respectively. The vacuum transfer robot 80 transfers the wafers W to the load lock module 20a or 20b via the loading/unloading ports 352.

According to this embodiment, it is possible to reduce the number of parts in the wafer processing apparatus 1 and simplify the configuration of the apparatus. Therefore, it is possible to reduce the cost of the apparatus.

### Fourth Embodiment

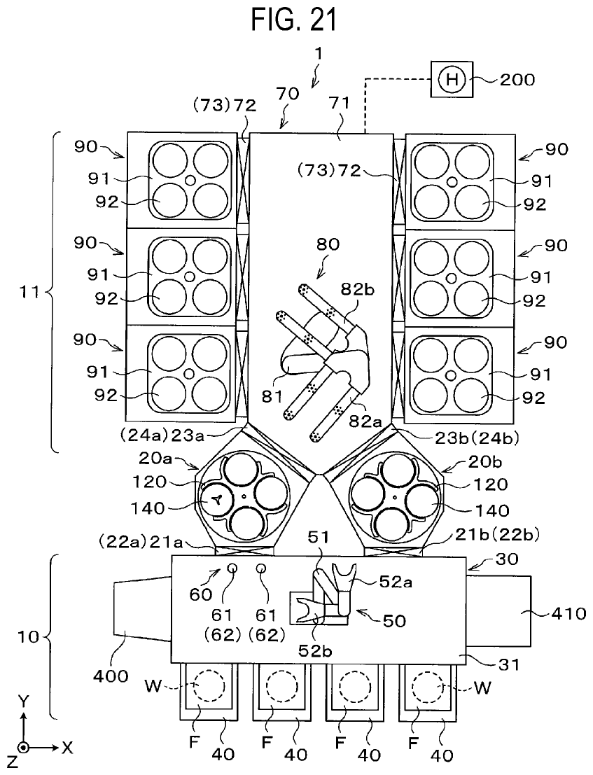

In the wafer processing apparatus 1 according to the above-described embodiment, the loader module 30 is provided with the position measurer 60, and the load lock module 20a is provided with the orienter 150. In this regard, as shown in FIG. 21, an orienter module 400 may be provided on a side surface of the housing 31 of the loader module 30 in the negative X-axis direction. The orienter module 400 adjusts the horizontal position of the wafer W as in Operation St1, and controls the notch orientation of the wafer W as in Operation St4. In such a case, the position measurer 60 and the orienter 150 may be still provided or omitted.

Further, as shown in FIG. 21, a cooling module 410 may be provided on the side surface of the housing 31 of the loader module 30 in the positive X-axis direction. The cooling module 410 cools the four wafers W to a desired temperature after the four wafers W are processed in the processing module 90 in Operation St8.

### Fifth Embodiment

In the wafer processing apparatus 1 of the above-described embodiment, the stage 140 is provided in each of the stage regions R1 to R4 in each of the load lock modules 20a and 20b. However, the stage 140 may be omitted. For example, in a case in which the heat treatment of the wafer W is not performed on the stage 140, the stage 140 may be omitted.

### Sixth Embodiment

In the wafer processing apparatus 1 according to the above-described embodiment, the four wafers W are collectively accommodated in each of the load lock modules 20a and 20b, the four wafers W are collectively transferred by the vacuum transfer robot 80, and the four wafers W are collectively processed in the processing module 90. In this regard, the number of wafers W to be collectively transferred and processed is not limited to four. For example, two or three wafers or five or more wafers W may be collectively transferred and processed.

### Seventh Embodiment

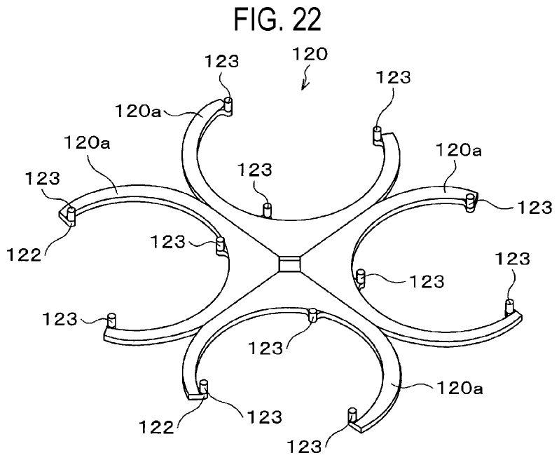

In the above-described embodiment, the rotary plates 120 of the load lock modules 20a and 20b are configured as a single unit. However, as shown in FIG. 22, the rotary plates 120 may be configured by combining a plurality of divided parts 120a. In the illustrated example, the rotary plate 120 is divided into four parts 120a, but the number of divisions of the rotary plate 120 is not limited thereto. In such a case, maintenance may be performed on each divided part 120a, which makes it possible to improve maintenance capacity.

The embodiments disclosed herein should be considered to be exemplary and not limitative in all respects. The above-described embodiments may be omitted, substituted, or modified in various ways without departing from the spirit and scope of the appended claims. For example, constituent elements of the above embodiments may be arbitrarily combined. From this arbitrary combination, it is needless to say that the operations and effects of the respective constituent elements related to the combination may be obtained, and other operations and other effects obvious to those skilled in the art may be obtained from the description of the present specification.

For example, in the above-described embodiments, the arrangement of a plurality of substrates (wafers) is determined with reference to the substrates to be transferred, such that the distance between adjacent substrates is less than half the radius of the substrate. However, the arrangement may also be determined with reference to the shape of the susceptor on which the substrates are arranged in the processing module 90 (a radius of the susceptor or a distance between adjacent susceptors).

According to the present disclosure, it is possible to improve a substrate transfer accuracy in a substrate processing apparatus that collectively transfers and processes a plurality of substrates.

Further, the effects described herein are illustrative or exemplary only and are not restrictive. That is, the technique of the present disclosure may obtain other effects obvious to those skilled in the art from the description herein in addition to or in place of the above effects.

The following configuration examples also belong to the technical scope of the present disclosure.
(1) A substrate processing apparatus for processing substrates, comprising:
a processing module including a plurality of stages and configured to process the substrates placed on the plurality of stages;
a first transfer module including a first transfer robot configured to collectively transfer the substrates with respect to the processing module;
a second transfer module including a second transfer robot configured to transfer the substrates with respect to a container capable of accommodating the substrates; and
a load lock module provided between the first transfer module and the second transfer module and configured to accommodate the substrates transferred by the first transfer robot or the second transfer robot,
wherein the load lock module includes:
a plurality of stage regions arranged around a center of a rotary support;
the rotary support including a plurality of fixed support pins for supporting the substrates and configured to be rotatable about the center as a rotation axis above the plurality of stage regions; and
a drive mechanism configured to drive the rotary support in a rotational direction, and
wherein, when transferring the substrates between the load lock module and the first transfer module or the second transfer module, the first transfer robot or the second transfer robot transfers the substrates with respect to the plurality of fixed support pins.
(2) In the substrate processing apparatus of (1) above, an arrangement of the substrates placed on the plurality of stages in the processing module is identical to an arrangement of the substrates supported on the rotary support in the load lock module, and
a distance between adjacent substrates in the arrangements of the plurality of substrates is less than ½ of a radius of each of the substrates.
(3) In the substrate processing apparatus of (1) or (2) above, the processing module includes:
a chamber in which the plurality of stages is accommodated;
a gas supply configured to supply a processing gas into the chamber; and
an exhauster configured to exhaust an interior of the chamber.
(4) In the substrate processing apparatus of any one of (1) to (3) above, the first transfer robot includes a first pick configured to be capable of holding the substrates and movable in a vertical direction,
the first transfer robot is configured to move the first pick in the vertical direction and transfer the substrates with respect to the plurality of fixed support pins,
the second transfer robot includes a second pick configured to be capable of holding the substrates and movable in the vertical direction, and
the second transfer robot is configured to move the second pick in the vertical direction and transfer the substrates with respect to the plurality of fixed support pins.
(5) In the substrate processing apparatus of any one of (1) to (4) above, the rotary support is configured to be movable in a vertical direction with respect to the plurality of stage regions, and
the drive mechanism is configured to drive the rotary support in the vertical direction.
(6) In the substrate processing apparatus of (5) above, a stage including a heat treatment mechanism is provided in each of the plurality of stage regions.
(7) In the substrate processing apparatus of any one of (1) to (6) above, the rotary support includes a plurality of arms having a substantially arc-like shape in a plan view and configured to be capable of supporting the substrates,
the plurality of fixed support pins are arranged at positions where the plurality of fixed support pins do not interfere with the first transfer robot when the first transfer robot transfers the substrates with respect to the plurality of fixed support pins, and where the plurality of fixed support pins do not interfere with the second transfer robot when the second transfer robot transfers the substrates with respect to the plurality of fixed support pins, and
each of the plurality of fixed support pins is provided inward of each of the plurality of arms to protrude upward of an upper surface of each of the plurality of arms.
(8) In the substrate processing apparatus of any one of (1) to (7) above, the plurality of fixed support pins come into point-contact with each of the substrates and support each of the substrates by a frictional force.
(9) In the substrate processing apparatus of any one of (1) to (8) above, the load lock module includes an orienter configured to control an orientation of a notch of each of the substrates with respect to the rotary support.
(10) In the substrate processing apparatus of (9) above, the orienter is configured to control an orientation of each of the substrates so that the notch of each of the substrates is oriented toward the center of the rotary support or a side opposite the center.
(11) In the substrate processing apparatus of (9) or (10) above, the orienter includes:
a notch detector configured to detect the notch of each of the substrates; and
a support pin provided in each of the plurality of stage regions and configured to be capable of supporting each of the substrates, rotatable in the rotational direction and movable in a vertical direction.
(12) In the substrate processing apparatus of any one of (9) to (11) above, the orienter is provided at a position corresponding to the substrate supported by the rotary support while being spaced apart from a substrate loading/unloading port of the load lock module, which is provided near the second transfer module.
(13) The substrate processing apparatus of any one of (1) to (12) above further includes a position measurer provided near the load lock module in the second transfer module and configured to measure a horizontal position of each of the substrates.
(14) In the substrate processing apparatus of any one of (1) to (13) above, the load lock module includes two load lock modules which are integrated.
(15) In the substrate processing apparatus of any one of (1) to (14) above, the plurality of stages provided in the processing module include four stages,
the first transfer robot is configured to be capable of collectively transferring four substrates, and
the rotary support in the load lock module is configured to be capable of supporting four substrates.
(16) A substrate processing method of processing substrates using a substrate processing apparatus,
wherein the substrate processing apparatus includes:
a processing module including a plurality of stages and configured to process the substrates placed on the plurality of stages;
a first transfer module including a first transfer robot configured to collectively transfer the substrates with respect to the processing module;
a second transfer module including a second transfer robot configured to transfer the substrates with respect to a container capable of accommodating the substrates; and
a load lock module provided between the first transfer module and the second transfer module and configured to accommodate the substrates transferred by the first transfer robot or the second transfer robot, and
wherein the load lock module includes:
a plurality of stage regions arranged around a center of a rotary support;
the rotary support including a plurality of fixed support pins for supporting the substrates and configured to be rotatable about the center as a rotation axis above the plurality of stage regions; and
a drive mechanism configured to drive the rotary support in a rotational direction, and
wherein the substrate processing method comprises:
an operation (a) of delivering the substrates from the second transfer robot to the plurality of fixed support pins and loading the substrates from the second transfer module into the load lock module;
an operation (b) of accommodating the substrates in the load lock module by repeatedly performing the operation (a) while rotating the rotary support;
an operation (c) of receiving the substrates supported by the plurality of fixed support pins by the first transfer robot and collectively unloading the substrates from the load lock module;
an operation (d) of delivering the substrates from the first transfer robot to the plurality of stages and collectively loading the substrates into the processing module from the first transfer module; and
an operation (e) of processing the substrates in the processing module.
(17) The substrate processing method of (16) above further includes:
an operation (f) of receiving the substrates placed on the plurality of stages by the first transfer robot and collectively unloading the substrates from the processing module to the first transfer module;
an operation (g) of delivering the substrates from the first transfer robot to the plurality of fixed support pins and collectively loading the substrates from the first transfer module to the load lock module; and
an operation (h) of receiving the substrates supported by the plurality of fixed support pins by the second transfer robot and unloading the substrates from the load lock module to the second transfer module.
(18) In the substrate processing method of (16) or (17) above, an arrangement of the substrates placed on the plurality of stages in the processing module is identical to an arrangement of the substrates supported on the rotary support in the load lock module, and
a distance between adjacent substrates in the arrangements of the substrates is less than ½ of a radius of each of the substrates.
(19) In the substrate processing method of any one of (16) to (18) above, the processing module includes:
a chamber in which the plurality of stages is accommodated;
a gas supply configured to supply a processing gas into the chamber; and
an exhauster configured to exhaust an interior of the chamber, and
wherein, in the operation (e), the substrates placed on the plurality of stages are processed by supplying the processing gas from the gas supply into the chamber and exhausting the interior of the chamber by the exhauster, and.
(20) In the substrate processing method of any one of (16) to (19) above, the first transfer robot includes a first pick configured to be capable of holding the substrate and movable in a vertical direction,
the second transfer robot includes a second pick configured to be capable of holding the substrates and movable in the vertical direction,
in the operation (a), when the second transfer robot delivers the substrates to the plurality of fixed support pins, the second pick moves in the vertical direction, and
in the operation (c), when the first transfer robot receives the substrates from the plurality of fixed support pins, the first pick moves in the vertical direction.
(21) In the substrate processing method of any one of (16) to (20) above, the rotary support is configured to be movable in a vertical direction with respect to the plurality of stage regions,
the drive mechanism is configured to drive the rotary support in the vertical direction,
a stage including a heat treatment mechanism is provided in each of the plurality of stage regions, and
after the operation (b) and before the operation (c), the rotary support is moved in the vertical direction to deliver the substrates supported on the rotary support to the plurality of stages where the substrates are thermally treated on the plurality of stages.
(22) In the substrate processing method of any one of (16) to (21) above, the load lock module includes an orienter configured to control an orientation of a notch of each of the substrates with respect to the rotary support, and
in the operation (b), an orientation of each of the substrates is controlled by the orienter so that the notch of each of the substrates is oriented toward the center of the rotary support or a side opposite the center.
(23) In the substrate processing method of any one of (16) to (22) above, the substrate processing apparatus includes a position measurer provided near the load lock module in the second transfer module and configured to measure a horizontal position of each of the substrates, and
before the operation (a), the horizontal position of the substrate is measured by the position measurer, and the horizontal position of the substrate is adjusted by the second transfer module.
(24) In the substrate processing method of any one of (16) to (23) above, in the operation (b), four substrates are accommodated in the load lock module,
in the operations (c) and (d), the first transfer robot collectively transfers the four substrates, and
in the operation (e), the four substrates are collectively processed in the processing module.

What is claimed is:

1. A substrate processing apparatus for processing substrates, comprising:
a processing module including a plurality of stages and configured to process the substrates placed on the plurality of stages;
a first transfer module including a first transfer robot configured to collectively transfer the substrates with respect to the processing module;
a second transfer module including a second transfer robot configured to transfer the substrates with respect to a container capable of accommodating the substrates; and
a load lock module provided between the first transfer module and the second transfer module and configured to accommodate the substrates transferred by the first transfer robot or the second transfer robot,
wherein the load lock module includes:
a plurality of stage regions arranged around a center of a rotary support;
the rotary support including a plurality of fixed support pins for supporting the substrates and configured to be rotatable about the center as a rotation axis above the plurality of stage regions; and
a drive mechanism configured to drive the rotary support in a rotational direction, and
wherein, when transferring the substrates between the load lock module and the first transfer module or the second transfer module, the first transfer robot or the second transfer robot transfers the substrates with respect to the plurality of fixed support pins.

2. The substrate processing apparatus of claim 1, wherein an arrangement of the substrates placed on the plurality of stages in the processing module is identical to an arrangement of the substrates supported on the rotary support in the load lock module, and
wherein a distance between adjacent substrates in the arrangements of the plurality of substrates is less than ½ of a radius of each of the substrates.

3. The substrate processing apparatus of claim 1, wherein the processing module includes:
a chamber in which the plurality of stages is accommodated;
a gas supply configured to supply a processing gas into the chamber; and
an exhauster configured to exhaust an interior of the chamber.

4. The substrate processing apparatus of claim 1, wherein the first transfer robot includes a first pick configured to be capable of holding the substrates and movable in a vertical direction,
wherein the first transfer robot is configured to move the first pick in the vertical direction and transfer the substrates with respect to the plurality of fixed support pins,
wherein the second transfer robot includes a second pick configured to be capable of holding the substrates and movable in the vertical direction, and
wherein the second transfer robot is configured to move the second pick in the vertical direction and transfer the substrates with respect to the plurality of fixed support pins.

5. The substrate processing apparatus of claim 1, wherein the rotary support is configured to be movable in a vertical direction with respect to the plurality of stage regions, and
wherein the drive mechanism is configured to drive the rotary support in the vertical direction.

6. The substrate processing apparatus of claim 5, wherein a stage including a heat treatment mechanism is provided in each of the plurality of stage regions.

7. The substrate processing apparatus of claim 1, wherein the rotary support includes a plurality of arms having a substantially arc-like shape in a plan view and configured to be capable of supporting the substrates,
wherein the plurality of fixed support pins are arranged at positions where the plurality of fixed support pins do not interfere with the first transfer robot when the first transfer robot transfers the substrates with respect to the plurality of fixed support pins, and where the plurality of fixed support pins do not interfere with the second transfer robot when the second transfer robot transfers the substrates with respect to the plurality of fixed support pins, and
wherein each of the plurality of fixed support pins is provided inward of each of the plurality of arms to protrude upward of an upper surface of each of the plurality of arms.

8. The substrate processing apparatus of claim 1, wherein the plurality of fixed support pins come into point-contact with each of the substrates and support each of the substrates by a frictional force.

9. The substrate processing apparatus of claim 1, wherein the load lock module includes an orienter configured to control an orientation of a notch of each of the substrates with respect to the rotary support.

10. The substrate processing apparatus of claim 9, wherein the orienter is configured to control an orientation of each of the substrates so that the notch of each of the substrates is oriented toward the center of the rotary support or a side opposite the center.

11. The substrate processing apparatus of claim 9, wherein the orienter includes:
a notch detector configured to detect the notch of each of the substrates; and
a support pin provided in each of the plurality of stage regions and configured to be capable of supporting each of the substrates, rotatable in the rotational direction and movable in a vertical direction.

12. The substrate processing apparatus of claim 9, wherein the orienter is provided at a position corresponding to the substrate supported by the rotary support while being spaced apart from a substrate loading/unloading port of the load lock module, which is provided near the second transfer module.

13. The substrate processing apparatus of claim 1, further comprising:
a position measurer provided near the load lock module in the second transfer module and configured to measure a horizontal position of each of the substrates.

14. The substrate processing apparatus of claim 1, wherein the load lock module includes two load lock modules which are integrated.

15. The substrate processing apparatus of claim 1, wherein the plurality of stages provided in the processing module include four stages,
wherein the first transfer robot is configured to be capable of collectively transferring four substrates, and
wherein the rotary support in the load lock module is configured to be capable of supporting four substrates.

16. A substrate processing method of processing substrates using a substrate processing apparatus,
wherein the substrate processing apparatus includes:
a processing module including a plurality of stages and configured to process the substrates placed on the plurality of stages;
a first transfer module including a first transfer robot configured to collectively transfer the substrates with respect to the processing module;
a second transfer module including a second transfer robot configured to transfer the substrates with respect to a container capable of accommodating the substrates; and
a load lock module provided between the first transfer module and the second transfer module and configured to accommodate the substrates transferred by the first transfer robot or the second transfer robot, and
wherein the load lock module includes:
a plurality of stage regions arranged around a center of a rotary support;
the rotary support including a plurality of fixed support pins for supporting the substrates and configured to be rotatable about the center as a rotation axis above the plurality of stage regions; and
a drive mechanism configured to drive the rotary support in a rotational direction, and
wherein the substrate processing method comprises:
an operation (a) of delivering the substrates from the second transfer robot to the plurality of fixed support pins and loading the substrates from the second transfer module into the load lock module;
an operation (b) of accommodating the substrates in the load lock module by repeatedly performing the operation (a) while rotating the rotary support;
an operation (c) of receiving the substrates supported by the plurality of fixed support pins by the first transfer robot and collectively unloading the substrates from the load lock module;
an operation (d) of delivering the substrates from the first transfer robot to the plurality of stages and collectively loading the substrates into the processing module from the first transfer module; and
an operation (e) of processing the substrates in the processing module.

17. The substrate processing method of claim 16, further comprising:
an operation (f) of receiving the substrates placed on the plurality of stages by the first transfer robot and collectively unloading the substrates from the processing module to the first transfer module;
an operation (g) of delivering the substrates from the first transfer robot to the plurality of fixed support pins and collectively loading the substrates from the first transfer module to the load lock module; and
an operation (h) of receiving the substrates supported by the plurality of fixed support pins by the second transfer robot and unloading the substrates from the load lock module to the second transfer module.

18. The substrate processing method of claim 16, wherein an arrangement of the substrates placed on the plurality of stages in the processing module is identical to an arrangement of the substrates supported on the rotary support in the load lock module, and
wherein a distance between adjacent substrates in the arrangements of the substrates is less than ½ of a radius of each of the substrates.

19. The substrate processing method of claim 16, wherein the processing module includes:
a chamber in which the plurality of stages is accommodated;
a gas supply configured to supply a processing gas into the chamber; and
an exhauster configured to exhaust an interior of the chamber, and
wherein, in the operation (e), the substrates placed on the plurality of stages are processed by supplying the processing gas from the gas supply into the chamber and exhausting the interior of the chamber by the exhauster.

20. The substrate processing method of claim 16, wherein the first transfer robot includes a first pick configured to be capable of holding the substrate and movable in a vertical direction,
wherein the second transfer robot includes a second pick configured to be capable of holding the substrates and movable in the vertical direction,
wherein, in the operation (a), when the second transfer robot delivers the substrates to the plurality of fixed support pins, the second pick moves in the vertical direction, and
wherein, in the operation (c), when the first transfer robot receives the substrates from the plurality of fixed support pins, the first pick moves in the vertical direction.
